(19) United States
(12) Patent Application Publication
(10) Pub. No.: US 2018/0145206 A1
(43) Pub. Date: May 24, 2018

(54) METHOD OF MANUFACTURING SEMICONDUCTOR DEVICE

(71) Applicant: Mitsubishi Electric Corporation, Chiyoda-ku, Tokyo (JP)

(72) Inventors: Kenji YOSHIKAWA, Chiyoda-ku, Tokyo (JP); Masato SUZUKI, Chiyoda-ku, Tokyo (JP)

(73) Assignee: Mitsubishi Electric Corporation, Chiyoda-ku, Tokyo (JP)

(21) Appl. No.: 15/580,134

(22) PCT Filed: Jul. 4, 2016
(86) PCT No.: PCT/JP2016/069764

§ 371 Date: Dec. 6, 2017

(30) Foreign Application Priority Data
Jul. 7, 2015 (JP) 2015-135801

(51) Int. Cl. H01L 33/00; H01L 23/544

(52) U.S. Cl. CPC H01L 33/005; H01L 2933/0033; H01L 23/544

(57) ABSTRACT

A method of manufacturing a semiconductor device includes: forming a plurality of semiconductor devices on a main surface of a wafer; forming a plurality of cleavage groove groups arranged on a division reference line; and cleaving the wafer along the division reference line to separate the plurality of semiconductor devices from each other. At least one of the plurality of cleavage groove groups is arranged for four semiconductor devices of the plurality of semiconductor devices. These four semiconductor devices are adjacent to each other. The plurality of cleavage groove groups each include a plurality of cleavage grooves arranged on the division reference line. Thereby, the semiconductor device can be improved in manufacturing yield.

### TECHNICAL FIELD

The present invention relates to a method of manufacturing a semiconductor device.

### BACKGROUND ART

There is a known method of manufacturing a semiconductor device, the method including: the first step of forming a plurality of semiconductor devices on a main surface of a wafer; the second step of forming a cleavage groove between the plurality of semiconductor devices; and the third step of applying a load to the wafer to cleave the wafer along the cleavage groove (see PTD 1).

### CITATION LIST

### Patent Document

### PTD 1: Japanese Patent Laying-Open No. 2003-86900

### SUMMARY OF INVENTION

### Technical Problem

The method of manufacturing a semiconductor device, however, poses a problem that a wafer is divided at the position largely deviated from a division reference line along which a cleavage groove is located, so that the manufacturing yield of the semiconductor device is decreased. By way of example, a plurality of semiconductor devices and a cleavage groove may be formed at an inclination in the azimuth angle direction in a main surface of the wafer with respect to the cleavage line of the wafer. If a plurality of semiconductor devices and a cleavage groove are formed at an inclination to the cleavage line of the wafer, the plurality of semiconductor devices are divided along the cleavage line of the wafer in the state where the division line of the semiconductor devices is not guided by the cleavage groove. Accordingly, the wafer is divided at the position largely deviated from the division reference line along which the cleavage groove is located, so that the manufacturing yield of the semiconductor device is decreased.

The present invention has been made in light of the above-described problems. An object of the present invention is to provide a method of manufacturing a semiconductor device, by which the semiconductor device can be improved in manufacturing yield.

### Solution to Problem

A method of manufacturing a semiconductor device of the present invention includes: forming a plurality of semiconductor devices arranged on a main surface of a wafer in a first direction and a second direction that intersects the first direction; forming a plurality of cleavage groove groups between the plurality of semiconductor devices; and cleaving the wafer along a division reference line to separate the plurality of semiconductor devices from each other. The plurality of cleavage groove groups are arranged on the division reference line. At least one of the plurality of cleavage groove groups is arranged for four semiconductor devices of the plurality of semiconductor devices, the four semiconductor devices being adjacent to each other in the first direction and the second direction. The plurality of cleavage groove groups each include a plurality of cleavage grooves arranged on the division reference line.

### Advantageous Effects of Invention

According to the method of manufacturing a semiconductor device of the present invention, a plurality of cleavage grooves included in each of a plurality of cleavage groove groups formed between a plurality of semiconductor devices can correct a division line such that the division line is brought sufficiently close to a division reference line. The plurality of cleavage groove groups each including the plurality of cleavage grooves can prevent a wafer from being divided at a position largely deviated from the division reference line. The method of manufacturing a semiconductor device of the present embodiment allows improvement in the manufacturing yield of the semiconductor device.

### BRIEF DESCRIPTION OF DRAWINGS

FIG. 1 is a diagram showing a flowchart of a method of manufacturing a semiconductor device according to the first embodiment of the present invention.

FIG. 2 is a schematic plan view illustrating one step of the method of manufacturing a semiconductor device according to the first embodiment of the present invention.

FIG. 3 is a schematic partial enlarged plan view of a region III shown in FIG. 2 in one step of the method of manufacturing a semiconductor device according to the first embodiment of the present invention.

FIG. 4 is a schematic partial enlarged cross-sectional view taken along a cross-sectional line IV-IV in FIG. 3, in one step of the method of manufacturing a semiconductor device according to the first embodiment of the present invention.

FIG. 5 is a schematic partial enlarged cross-sectional view in one step of the method of manufacturing a semiconductor device according to the first modification of the first embodiment of the present invention.

FIG. 6 is a schematic partial enlarged cross-sectional view in one step of the method of manufacturing a semiconductor device according to the second modification of the first embodiment of the present invention.

FIG. 7 is a schematic partial enlarged perspective view illustrating the step of cleaving a wafer in the method of manufacturing a semiconductor device according to the first embodiment of the present invention.

FIG. 8 is a schematic partial enlarged plan view illustrating the step of cleaving a wafer in the method of manufacturing a semiconductor device according to the first embodiment of the present invention.

FIG. 9 is a schematic partial enlarged cross-sectional view of the wafer obtained after the step of cleaving a wafer in the method of manufacturing a semiconductor device according to the first embodiment of the present invention.

FIG. 10 is a diagram showing a graph representing an effect of correcting a division plane by a cleavage groove group in the method of manufacturing a semiconductor device according to the first embodiment of the present invention.

FIG. 11 is a schematic partial enlarged plan view in one step of a method of manufacturing a semiconductor device according to the second embodiment of the present invention.

FIG. 12 is a schematic partial enlarged cross-sectional view of a wafer obtained after the step of cleaving a wafer in the method of manufacturing a semiconductor device according to the second embodiment of the present invention.

FIG. 13 is a schematic partial enlarged plan view in one step of a method of manufacturing a semiconductor device according to the third embodiment of the present invention.

FIG. 14 is a schematic partial enlarged plan view in one step of a method of manufacturing a semiconductor device according to the fourth embodiment of the present invention.

FIG. 15 is a diagram showing a flowchart of a method of manufacturing a semiconductor device according to the fifth embodiment of the present invention.

FIG. 16 is a schematic plan view illustrating one step of the method of manufacturing a semiconductor device according to the fifth embodiment of the present invention.

FIG. 17 is a schematic partial enlarged plan view of a guide groove group in the method of manufacturing a semiconductor device according to the fifth embodiment of the present invention.

FIG. 18 is a schematic partial enlarged perspective view illustrating the step of cleaving a wafer in the method of manufacturing a semiconductor device according to the fifth embodiment of the present invention.

FIG. 19 is a schematic partial enlarged plan view illustrating the step of cleaving a wafer in the method of manufacturing a semiconductor device according to the fifth embodiment of the present invention.

FIG. 20 is a diagram showing a cross-sectional photograph of a cleavage plane of the wafer obtained after the step of cleaving a wafer in the method of manufacturing a semiconductor device according to the fifth embodiment of the present invention.

FIG. 21 is a schematic partial enlarged perspective view of the wafer obtained after the step of cleaving a wafer in the method of manufacturing a semiconductor device according to the fifth embodiment of the present invention.

FIG. 22 is a schematic partial enlarged plan view illustrating one step of a method of manufacturing a semiconductor device in a comparative example.

FIG. 23 is a diagram showing a graph representing an effect of correcting a division line by a guide groove in the method of manufacturing a semiconductor device according to the fifth embodiment of the present invention.

FIG. 24 is a schematic partial enlarged plan view of a guide groove group in a method of manufacturing a semiconductor device according to the sixth embodiment of the present invention.

FIG. 25 is a schematic partial enlarged plan view of a guide groove group in a method of manufacturing a semiconductor device according to the seventh embodiment of the present invention.

FIG. 26 is a schematic partial enlarged plan view of a guide groove group in a method of manufacturing a semiconductor device according to the eighth embodiment of the present invention.

FIG. 27 is a schematic partial enlarged plan view of a guide groove group in a method of manufacturing a semiconductor device according to the ninth embodiment of the present invention.

FIG. 28 is a schematic partial enlarged plan view of a guide groove group in a method of manufacturing a semiconductor device according to the tenth embodiment of the present invention.

FIG. 29 is a diagram showing a flowchart of a method of manufacturing a semiconductor device according to the eleventh embodiment of the present invention.

FIG. 30 is a schematic plan view illustrating one step of the method of manufacturing a semiconductor device according to the eleventh embodiment of the present invention.

FIG. 31 is a schematic partial enlarged plan view of a guide groove group in the method of manufacturing a semiconductor device according to the eleventh embodiment of the present invention.

FIG. 32 is a schematic partial enlarged plan view of a guide groove group in a method of manufacturing a semiconductor device according to the twelfth embodiment of the present invention.

FIG. 33 is a schematic partial enlarged plan view of a guide groove group in a method of manufacturing a semiconductor device according to the thirteenth embodiment of the present invention.

FIG. 34 is a schematic partial enlarged plan view of a guide groove group in a method of manufacturing a semiconductor device according to the fourteenth embodiment of the present invention.

FIG. 35 is a diagram showing a flowchart of a method of manufacturing a semiconductor device according to the fifteenth embodiment of the present invention.

FIG. 36 is a schematic plan view illustrating one step of the method of manufacturing a semiconductor device according to the fifteenth embodiment of the present invention.

FIG. 37 is a schematic partial enlarged plan view of a region XXXVII shown in FIG. 36 in one step of the method of manufacturing a semiconductor device according to the fifteenth embodiment of the present invention.

### DESCRIPTION OF EMBODIMENTS

Embodiments of the present invention will be hereinafter described. The same configurations are designated by the same reference characters, and description thereof will not be repeated.

### First Embodiment

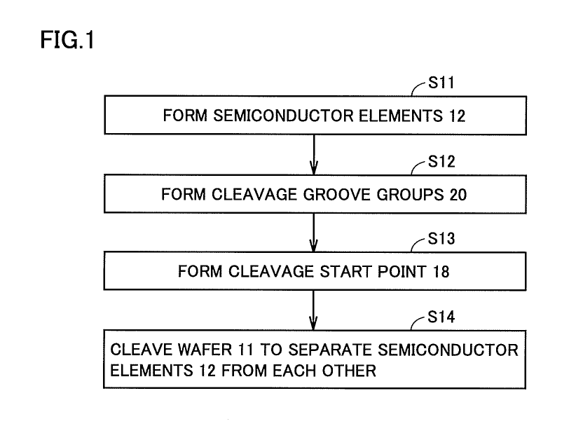

Referring to FIGS. 1 to 10, a method of manufacturing a semiconductor device 12 according to the first embodiment will be hereinafter described.

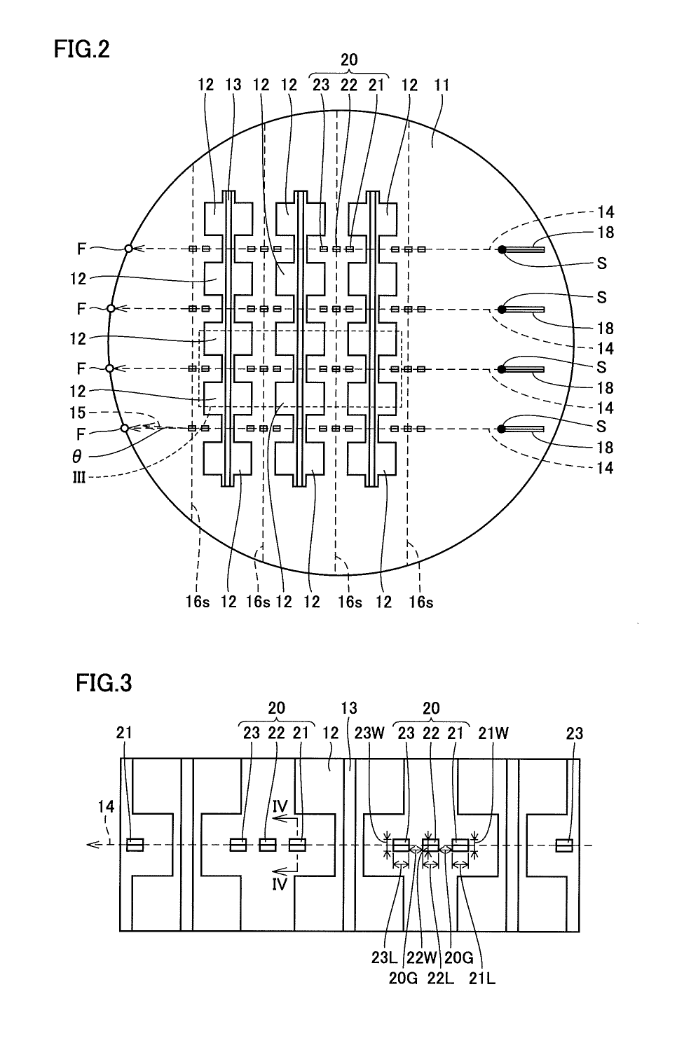

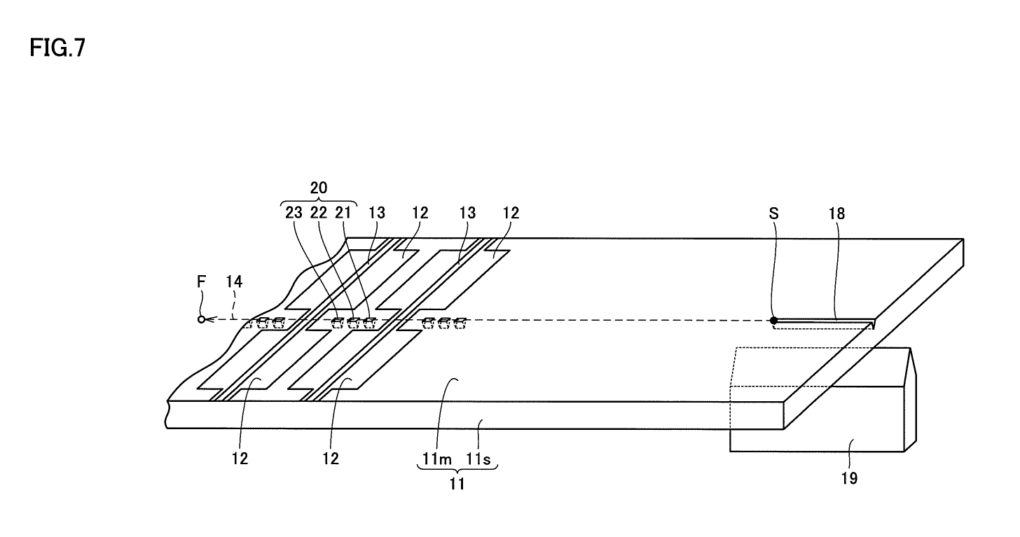

Referring to FIGS. 1 and 2, the method of manufacturing a semiconductor device 12 according to the present embodiment includes: forming, in a first region on a main surface 11m of a wafer 11 (see FIG. 7), a plurality of semiconductor devices 12 arranged in a first direction and a second direction that intersects the first direction (S11). The material of wafer 11 is not particularly limited, but may be indium phosphide (InP), for example. Specifically, the second direction may be orthogonal to the first direction. The first direction may be parallel to a division reference line 14. In the present embodiment, a plurality of semiconductor devices 12 are formed so as to be inclined in the azimuth angle direction in main surface 11m of wafer 11 (see FIG. 7) with respect to a cleavage line 15 of wafer 11.

In the present specification, cleavage line 15 means a line of intersection of cleavage plane 11s of wafer 11 (see FIG. 7) and main surface 11 m of wafer 11. Cleavage plane 11s of wafer 11 means a crystal plane of wafer 11 that has cleavability. In the present specification, division reference line 14 means a line used as a reference for dividing wafer 11.

The plurality of semiconductor devices 12 include a semiconductor layer, an insulating layer, and an electrode, for example. For example, using the sputtering method, the vacuum evaporation method or the chemical vapor deposition (CVD) method, a semiconductor layer, an insulating layer and an electrode may be deposited on main surface 11m of wafer 11, thereby forming a plurality of semiconductor devices 12. In the present embodiment, semiconductor devices 12 are light emitting diodes or semiconductor lasers, and each include an active region 13. The plurality of semiconductor devices 12 are divided to obtain active regions 13. From each of active regions 13 in the plurality of semiconductor devices 12, light is emitted. In the present embodiment, the direction in which active region 13 extends is set so as to be inclined in the azimuth angle direction in main surface 11m of wafer 11 (see FIG. 7) with respect to cleavage line 15. Semiconductor devices 12 are not limited to light emitting diodes or semiconductor lasers, but may be transistors having a vertical structure or a horizontal structure, for example.

Referring to FIGS. 1 to 3, the method of manufacturing a semiconductor device 12 according to the present embodiment includes: forming a plurality of cleavage groove groups 20 between a plurality of semiconductor devices 12 in the first region on main surface 11m of wafer 11 (S12); and forming a cleavage start point 18 in the second region on main surface 11m of wafer 11 (see FIG. 7) that is different from the first region (S13). The plurality of cleavage groove groups 20 and cleavage start point 18 are located on division reference line 14. At least one of the plurality of cleavage groove groups 20 is arranged for four semiconductor devices 12 of the plurality of semiconductor devices 12, the four semiconductor devices 12 being adjacent to each other in the first direction and the second direction. Each of the plurality of cleavage groove groups 20 includes a plurality of cleavage grooves 21, 22 and 23 located on division reference line 14.

A plurality of cleavage groove groups 20 are arranged for one division reference line 14. Division reference line 14 is located between two semiconductor devices 12 adjacent to each other in the second direction.

Referring to FIGS. 2, 8 and 9, among the plurality of cleavage groove groups 20, two cleavage groove groups 20 adjacent to each other in the first direction are arranged symmetrically with respect to active region 13. Specifically, a first distance d₁ between active region 13 and a cleavage groove group 20 that is located close to cleavage start point 18 relative to active region 13 is equal to a second distance d₂ between active region 13 and a cleavage groove group 20 that is located on the opposite side of active region 13 from cleavage start point 18. First distance d₁ is defined as a distance between the center line of active region 13 and a cleavage groove group 20 located close to cleavage start point 18 relative to active region 13. Second distance d₂ is defined as a distance between the center line of active region 13 and a cleavage groove group 20 that is located on the opposite side of active region 13 from cleavage start point 18.

In the present embodiment, the plurality of cleavage groove groups 20 are formed so as not to contact active region 13. The plurality of cleavage grooves 21, 22 and 23 are provided so as to be inclined in the azimuth angle direction in main surface 11m of wafer 11 with respect to cleavage line 15. The direction in which the plurality of cleavage grooves 21, 22 and 23 are arranged is orthogonal to the direction in which active region 13 extends.

Either forming a plurality of cleavage groove groups 20 (S12) or forming a cleavage start point 18 (S13) may be performed first. Alternatively, forming a plurality of cleavage groove groups 20 (S12) and forming a cleavage start point 18 (S13) may be simultaneously performed. Forming a plurality of cleavage groove groups 20 (S12) and forming a cleavage start point 18 (S13) may be performed simultaneously with forming a device separation groove (not shown) in semiconductor device 12 so as to be arranged along a device separation line 16s. Thereby, the manufacturing time of semiconductor device 12 may be shortened. Device separation line 16s is located between two semiconductor devices 12 adjacent to each other in the first direction.

Forming a plurality of cleavage groove groups 20 may also include etching wafer 11. Forming a cleavage start point 18 may also include forming a cleavage start point groove (18). Cleavage start point 18 may be a cleavage start point groove (18). If cleavage start point 18 is a cleavage start point groove (18), forming a cleavage start point 18 may also include etching wafer 11. The plurality of cleavage groove groups 20 and cleavage start point groove (18) may be formed in a common step. Forming a plurality of cleavage groove groups 20 and cleavage start point groove (18) in a common step means that a cleavage start point groove (18) is also formed in the step of forming a plurality of cleavage groove groups 20. Each of the plurality of cleavage grooves 21, 22 and 23 included in each of the plurality of cleavage groove groups 20 has a depth of 10 μm, for example.

Specifically, the plurality of cleavage groove groups 20 and cleavage start point groove (18) may be formed by etching wafer 11 using a mask having an opening formed by the photolithography process. For example, a silicon dioxide (SiO₂) film is formed by the sputtering method or the plasma CVD method on main surface 11m of wafer 11 on which a plurality of semiconductor devices 12 are formed. A resist is formed on the SiO₂ film. An opening is provided in the resist using the photolithography process.

The resist having an opening provided therein is used to dry etch the SiO₂ film, thereby providing an opening in the SiO₂ film. When the SiO₂ film is dry etched, gas made of a compound containing elements such as carbon, hydrogen, and fluoride may be used as etching gas. The SiO₂ film having an opening provided therein is used as a mask for etching wafer 11. This etching of wafer 11 may be performed, for example, by dry etching such as inductively coupled plasma reactive ion etching (ICP-RIE), or by wet etching using a hydrochloric acid-based echant. In this way, a plurality of cleavage groove groups 20 and cleavage start point groove (18) may be formed in wafer 11 in a common etching step.

In the method of manufacturing a semiconductor device 12 of the present embodiment, forming a plurality of cleavage groove groups 20 may include forming a plurality of cleavage grooves 21, 22 and 23 having the same bottom surface area when seen in a plan view of main surface 11m of wafer 11. When seen in a plan view of the main surface of wafer 11, the plurality of cleavage grooves 21, 22 and 23 have the same bottom surface area. Accordingly, the mask openings having the same area are applied when wafer 11 is etched to form a plurality of cleavage grooves 21, 22 and 23. When a plurality of cleavage grooves 21, 22 and 23 included in cleavage groove group 20 are simultaneously formed, the plurality of cleavage grooves 21, 22 and 23 may be suppressed from having different depths. According to the method of manufacturing a semiconductor device 12 of the present embodiment, the accuracy in correcting division line 16 toward division reference line 14 by the plurality of cleavage grooves 21, 22 and 23 is further improved, so that cleavage of wafer 11 largely deviated from division reference line 14 may be further suppressed.

On the other hand, if the mask openings have different areas, a plurality of cleavage grooves having different depths are to be formed. If the cleavage grooves are relatively deep, wafer 11 is more likely to break in the relatively deep cleavage grooves. If the cleavage grooves are relatively shallow, it becomes difficult for the relatively shallow cleavage grooves to correct division line 16.

In the present specification, division line 16 means the line of intersection of the division plane and main surface 11m of wafer 11. In the present specification, the division plane means the plane along which wafer 11 is actually divided when wafer 11 is cleaved.

In the present embodiment, each of the plurality of cleavage groove groups 20 includes three cleavage grooves 21, 22 and 23. Each of the plurality of cleavage groove groups 20 may also include two cleavage grooves, or may also include four or more cleavage grooves. Cleavage groove 22 is located on the opposite side of cleavage start point 18 with respect to cleavage groove 21 (on the end point F side) so as to be spaced at a distance 20G from cleavage groove 21. Cleavage groove 23 is located on the opposite side of cleavage start point 18 with respect to cleavage groove 22 (on the end point F side) so as to be spaced at a distance 20G from cleavage groove 22. The distance between cleavage groove 21 and cleavage groove 22 may be equal to or different from the distance between cleavage groove 22 and cleavage groove 23. When distance 20G between the plurality of cleavage grooves 21, 22 and 23 adjacent to each other is increased, the number of cleavage grooves 21, 22 and 23 is reduced. Thus, for example, when wafer 11 is made of an InP material, it is preferable that distance 20G between the plurality of cleavage grooves 21, 22 and 23 adjacent to each other is 100 μm or less.

When seen in a plan view of main surface 11m of wafer 11, each of three cleavage grooves 21, 22 and 23 may have an elongated shape extending in the direction along division reference line 14. Cleavage groove 21 has a groove length 21L extending in the direction along division reference line 14, and has a groove width 21W extending in the direction orthogonal to division reference line 14. Cleavage groove 22 has a groove length 22L extending in the direction along division reference line 14, and has a groove width 22W extending in the direction orthogonal to division reference line 14. Cleavage groove 23 has a groove length 23L extending in the direction along division reference line 14, and has a groove width 23W extending in the direction orthogonal to division reference line 14. The center of groove width 21W of cleavage groove 21, the center of groove width 22W of cleavage groove 22, and the center of groove width 23W of cleavage groove 23 may be located on division reference line 14. Cleavage groove 21, cleavage groove 22 and cleavage groove 23 may have the same shape or may have different shapes. Groove length 21L, groove length 22L and groove length 23L may be equal to or different from each other. Groove width 21W, groove width 22W and groove width 23W may be equal to or different from each other.

For example, when wafer 11 is made of an InP material, the plurality of cleavage grooves 21, 22 and 23 may have groove lengths (21L, 22L, 23L), each of which may be 5 μm or more and 100 μm or less, and preferably 10 μm or more and 50 μm or less. When the groove lengths (21L, 22L, 23L) of the plurality of cleavage grooves 21, 22 and 23 are reduced, the depths of cleavage grooves 21, 22 and 23 are reduced. When the groove lengths (21L, 22L, 23L) and the depths of cleavage grooves 21, 22 and 23 are reduced, it becomes difficult to bring division line 16 closer to division reference line 14 by the plurality of cleavage grooves 21, 22 and 23. Thus, it is preferable that the plurality of cleavage grooves 21, 22 and 23 have groove lengths (21L, 22L, 23L) of 5 μm or more. When the groove lengths (21L, 22L, 23L) of the plurality of cleavage grooves 21, 22 and 23 are increased, the number of the plurality of cleavage grooves 21, 22 and 23 is reduced. When the number of the plurality of cleavage grooves 21, 22 and 23 is reduced, it becomes difficult to bring division line 16 closer to division reference line 14. Accordingly, it is preferable that each of the plurality of cleavage grooves 21, 22 and 23 has a groove length (21L, 22L, 23L) of 100 μm or less.

For example, when wafer 11 is made of an InP material, each of the plurality of cleavage grooves 21, 22 and 23 may have a groove width (21W, 22W, 23W) of 1 μm or more and 20 μm or less, and preferably 5 μm or more and 15 μm or less. When the groove widths (21W, 22W, 23W) of the plurality of cleavage grooves 21, 22 and 23 are reduced, the depths of cleavage grooves 21, 22 and 23 are reduced. When the groove widths (21W, 22W, 23W) and the depths of cleavage grooves 21, 22 and 23 are reduced, it becomes difficult to bring division line 16 closer to division reference line 14 by the plurality of cleavage grooves 21, 22 and 23. Accordingly, it is preferable that each of the plurality of cleavage grooves 21, 22 and 23 has a groove width (21W, 22W, 23W) of 1 μm or more. When the groove widths (21W, 22W, 23W) of the plurality of cleavage grooves 21, 22 and 23 are increased, the ends of the groove widths (21W, 22W, 23W) of the plurality of cleavage grooves 21, 22 and 23 are distanced away from division reference line 14, so that it becomes difficult to bring division line 16 closer to division reference line 14 by the plurality of cleavage grooves 21, 22 and 23. Thus, it is preferable that each of the plurality of cleavage grooves 21, 22 and 23 has a groove width (21W, 22W, 23W) of 20 μm or less.

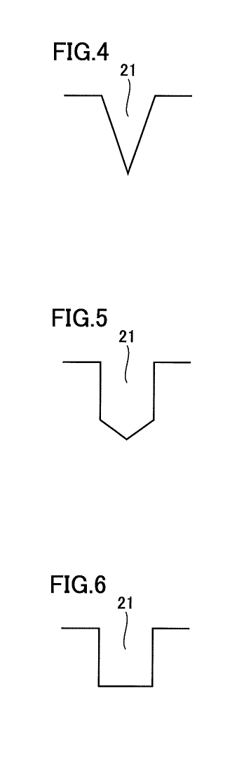

Each of the plurality of cleavage grooves 21, 22 and 23 may have a V-shaped cross section orthogonal to division reference line 14 as shown in FIGS. 4 and 5. As shown in FIGS. 4 and 5, the bottom surface of each of the plurality of cleavage grooves 21, 22 and 23 may have a V-shaped cross section orthogonal to division reference line 14. The plurality of cleavage grooves 21, 22 and 23 each having a V shape may be formed, for example, by wet etching wafer 11. As shown in FIG. 6, each of the plurality of cleavage grooves 21, 22 and 23 may have a rectangular cross section orthogonal to division reference line 14. As shown in FIG. 6, the bottom surface of each of the plurality of cleavage grooves 21, 22 and 23 may have a flat cross section orthogonal to division reference line 14.

When cleaving a wafer 11 in which a plurality of cleavage grooves 21, 22 and 23 each having a V shape as shown in FIGS. 4 and 5 are formed, stress concentrates at the V-shaped groove end of each of the plurality of cleavage grooves 21, 22 and 23. Thus, wafer 11 is more likely to be cleaved at the center of each of the groove widths (21W, 22W, 23W) of the plurality of cleavage grooves 21, 22 and 23 each having a V shape. The plurality of cleavage grooves 21, 22 and 23 each having a V shape can more accurately bring division line 16 closer to division reference line 14.

The method of manufacturing a semiconductor device 12 according to the present embodiment may further include grinding wafer 11. The method of manufacturing a semiconductor device 12 according to the present embodiment may further include forming a backside electrode on the backside surface of wafer 11 that is on the opposite side of main surface 11m of wafer 11.

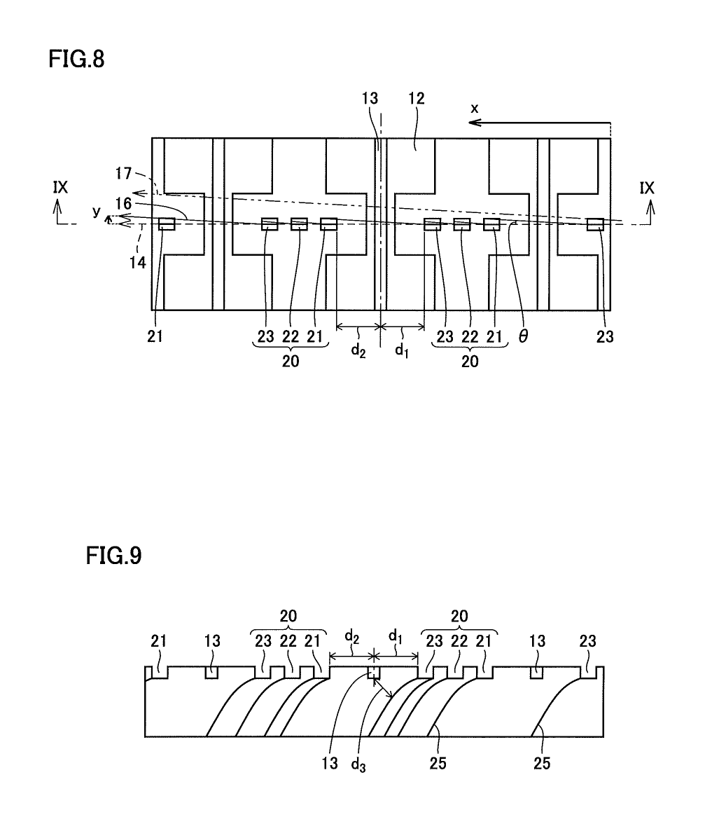

Referring to FIGS. 1 and 7 to 9, the method of manufacturing a semiconductor device 12 according to the present embodiment includes cleaving wafer 11 to separate the plurality of semiconductor devices 12 from each other (S14). Specifically, a blade 19 is pressed against wafer 11 from the backside of wafer 11 to apply a load to wafer 11. Wafer 11 is cleaved from cleavage start point 18 along cleavage line 15. For example, when wafer 11 has main surface 11m of a (100) plane, cleavage plane 11s corresponds to a (0-1-1) plane, and wafer 11 is cleaved from cleavage start point 18 in the [01-1] direction or in the [0-11] direction. As shown in FIGS. 2 and 7, wafer 11 is cleaved along division reference line 14 from a start point S shown by a black circle toward an end point F shown by a white circle. In the present embodiment, start point S and end point F are located on division reference line 14. Wafer 11 is cleaved from cleavage start point 18 in the direction along main surface 11m of wafer 11 and in the thickness direction of wafer 11 that is orthogonal to main surface 11m of wafer 11. In the present embodiment, in main surface 11m of wafer 11, a plurality of semiconductor devices 12 and a plurality of cleavage grooves 21, 22 and 23 are formed so as to be inclined in the azimuth angle direction in main surface 11m of wafer 11 with respect to cleavage line 15 of wafer 11. Referring to FIG. 8, division reference line 14 corresponding to the direction in which the plurality of cleavage grooves 21, 22 and 23 are arranged is deviated by an azimuth angle θ with respect to cleavage line 15. Cleavage line 15 is parallel to a division line 17 in the case of no grooves, which will be described later. Wafer 11 is divided from cleavage start point 18 along cleavage line 15 that is inclined by azimuth angle θ with respect to division reference line 14. Inclination of division reference line 14 with respect to cleavage line 15 in the azimuth angle direction in main surface 11m of wafer 11 results from, for example, the angle deviation of the orientation flat of wafer 11, the pattern deviations of the plurality of semiconductor devices 12 in the photolithography process, and the like.

In the present embodiment, a plurality of cleavage groove groups 20 are formed between the plurality of semiconductor devices 12. Each of the plurality of cleavage groove groups 20 includes a plurality of cleavage grooves 21, 22 and 23 arranged on division reference line 14. Wafer 11 does not exist in each of the plurality of cleavage grooves 21 and 22 and 23, whereas wafer 11 exists around the circumference of each of the plurality of cleavage grooves 21, 22 and 23. Thus, stress is generated at the edge portion of each of the plurality of cleavage grooves 21, 22 and 23, that is, at the portion of wafer 11 that faces each of the plurality of cleavage grooves 21, 22 and 23.

The direction of this stress is orthogonal to division reference line 14 at the first end of each of the plurality of cleavage grooves 21, 22 and 23 that is located on the opposite side of cleavage start point 18 (on the end point F side) and at the second end of each of the plurality of cleavage grooves 21, 22 and 23 that is located close to cleavage start point 18 (on the start point S side). Due to this stress, at the first end of each of the plurality of cleavage grooves 21, 22 and 23, division line 16 inclined by azimuth angle θ with respect to division reference line 14 is corrected so as to be brought closer to division reference line 14. Due to this stress, at the first end of each of the plurality of cleavage grooves 21, 22 and 23, division line 16 is corrected toward division reference line 14.

As shown in FIG. 9, when the plurality of cleavage grooves 21, 22 and 23 correct division line 16 toward division reference line 14, a level difference 25 is formed on division line 16 and the division plane. This level difference 25 extends from each of the plurality of cleavage grooves 21, 22 and 23 in (i) the direction from cleavage start point 18 toward the opposite side of cleavage start point 18 (the direction from start point S toward end point F), and (ii) the direction from main surface 11m of wafer 11 toward the backside surface of wafer 11. The size of level difference 25 corresponds to the amount of correction of division line 16 and the division plane in each of the plurality of cleavage grooves 21, 22 and 23.

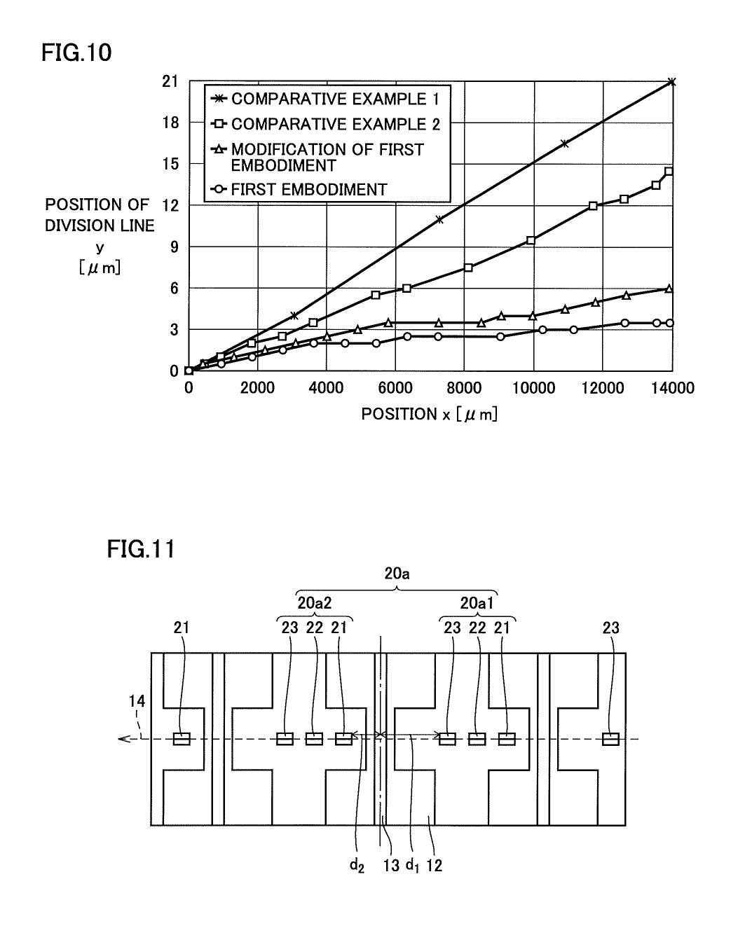

Referring to FIG. 10, the effect of correcting division line 16 by cleavage groove group 20 will be hereinafter described. A position x on the horizontal axis in FIG. 10 indicates the position in wafer 11 in the direction along division reference line 14. Position x located on the cleavage start point 18 side in semiconductor device 12 that is located closest to cleavage start point 18 is defined as 0 μm. Position x located on the opposite side of cleavage start point 18 in semiconductor device 12 that is farthest away from cleavage start point 18 may be defined as 14000 μm, for example. A position y of division line 16 on the vertical axis in FIG. 10 indicates the magnitude of deviation of division line 16 from division reference line 14 at position x (the distance between division reference line 14 and division line 16).

Division reference line 14 is inclined by azimuth angle θ with respect to cleavage line 15. Thus, in comparative example 1 in which a plurality of cleavage grooves 21, 22 and 23 are not formed, division line 16 largely deviates from division reference line 14 as division line 16 is distanced away from cleavage start point 18, as shown by division line 17 in the case of no grooves in FIG. 8. In comparative example 2, one cleavage groove is provided for four semiconductor devices 12 adjacent to each other in the first direction and the second direction. The cleavage groove in comparative example 2 cannot correct division line 16 so as to bring division line 16 sufficiently closer to division reference line 14.

On the other hand, in the present embodiment, one cleavage groove group 20 is provided for four semiconductor devices 12 adjacent to each other in the first direction and the second direction. Each of the plurality of cleavage groove groups 20 includes three cleavage grooves 21, 22 and 23. A positions y of division line 16 in semiconductor device 12 that is farthest away from cleavage start point 18 in the present embodiment lowers to one-third or less of that in comparative example 1. According to the present embodiment, division line 16 may be corrected so as to be sufficiently brought closer to division reference line 14 by cleavage groove group 20 including a plurality of cleavage grooves 21, 22 and 23 between the plurality of semiconductor devices 12.

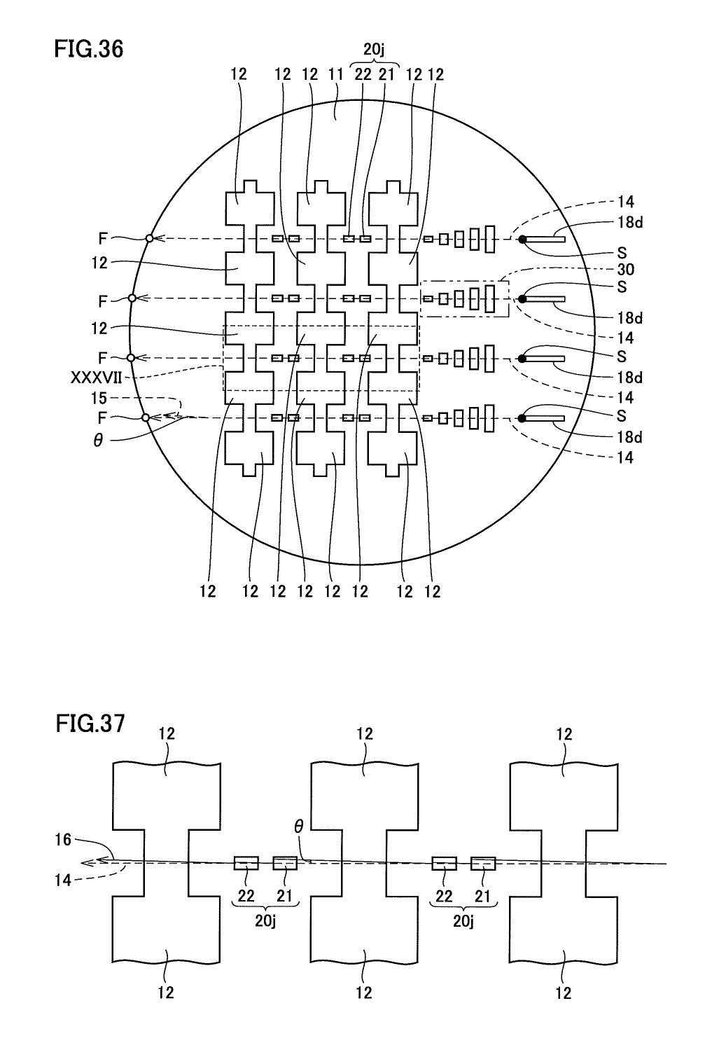

In a modification of the present embodiment, each of the plurality of cleavage groove groups includes two cleavage grooves (for example, a cleavage groove group 20j shown in FIGS. 36, and 37). Position y of division line 16 in semiconductor device 12 that is farthest away from cleavage start point 18 in the modification of the present embodiment lowers to one-third or less of that in comparative example 1. Also in the modification of the present embodiment, division line 16 may be corrected so as to be brought sufficiently closer to division reference line 14 by the cleavage groove group including two cleavage grooves between the plurality of semiconductor devices 12.

Cleaving a wafer 11 to separate the plurality of semiconductor devices 12 from each other (S14) may include separating the plurality of semiconductor devices 12 from each other along device separation line 16s on which the device separation groove is located.

The effect of the method of manufacturing a semiconductor device 12 of the present embodiment will be hereinafter described.

The method of manufacturing a semiconductor device 12 of the present embodiment includes forming a plurality of semiconductor devices 12 arranged along the first region on main surface 11m of wafer 11 so as to extend in the first direction and the second direction that intersects the first direction (S11). The method of manufacturing a semiconductor device 12 according to the present embodiment includes: forming a plurality of cleavage groove groups 20 between the plurality of semiconductor devices 12 in the first region on main surface 11m of wafer 11 (S12); and forming a cleavage start point 18 in the second region on main surface 11m of wafer 11 that is different from the first region (S13). The method of manufacturing a semiconductor device 12 according to the present embodiment includes cleaving wafer 11 along division reference line 14 to separate the plurality of semiconductor devices 12 from each other (S14). The plurality of cleavage groove groups 20 and cleavage start point 18 are arranged on division reference line 14. At least one of the plurality of cleavage groove groups 20 is arranged for four semiconductor devices 12 of the plurality of semiconductor devices 12, in which the four semiconductor devices 12 are adjacent to each other in the first direction and the second direction. The plurality of cleavage groove groups 20 each include a plurality of cleavage grooves 21, 22 and 23 located on division reference line 14.

According to the method of manufacturing a semiconductor device 12 of the present embodiment, even if division reference line 14 is inclined in the azimuth angle direction in main surface 11m of wafer 11 with respect to cleavage line 15 of wafer 11, the plurality of cleavage grooves 21, 22 and 23 included in each of the plurality of cleavage groove groups 20 formed between the plurality of semiconductor devices 12 can correct division line 16 such that division line 16 is brought sufficiently closer to division reference line 14. The plurality of cleavage groove groups 20 each including a plurality of cleavage grooves 21, 22 and 23 can prevent wafer 11 from being divided at the position largely deviated from division reference line 14. According to the method of manufacturing a semiconductor device 12 of the present embodiment, semiconductor device 12 can be improved in manufacturing yield.

According to the method of manufacturing a semiconductor device 12 of the present embodiment, the plurality of cleavage grooves 21, 22 and 23 may each have a V-shaped in a cross section that is orthogonal to division reference line 14. When wafer 11 is cleaved, stress concentrates at the V-shaped groove end of each of the plurality of cleavage grooves 21, 22 and 23. Wafer 11 is more likely to be cleaved at the center of each of the groove widths (21W, 22W, 23W) of the plurality of cleavage grooves 21, 22 and 23 each having a V shape. The plurality of cleavage grooves 21, 22 and 23 each having a V shape can bring division line 16 closer to division reference line 14 more accurately.

In the method of manufacturing a semiconductor device 12 of the present embodiment, forming the cleavage start point 18 may include etching wafer 11 to provide a cleavage start point groove (18). Forming cleavage start point groove (18) by etching suppresses formation of cracks around the cleavage start point groove (18). According to the method of manufacturing a semiconductor device 12 of the present embodiment, cleavage of wafer 11 at the position largely deviated from division reference line 14 due to these cracks is suppressed, and wafer 11 may be cleaved along division reference line 14. On the other hand, when the cleavage start point groove (18) is provided on wafer 11 by scribing, cracks extending in various directions are to be formed around the cleavage start point groove (18). Due to these clacks, wafer 11 may be cleaved at the position largely deviated from division reference line 14.

In the method of manufacturing a semiconductor device 12 of the present embodiment, the plurality of cleavage groove groups 20 and cleavage start point groove (18) may be provided in a common step. According to the method of manufacturing a semiconductor device 12 of the present embodiment, the number of steps of manufacturing semiconductor device 12 can be decreased, so that semiconductor device 12 can be manufactured efficiently.

In the method of manufacturing a semiconductor device 12 of the present embodiment, forming the plurality of cleavage groove groups 20 may include forming a plurality of cleavage grooves 21, 22 and 23 having the same bottom surface area when seen in a plan view of main surface 11m of wafer 11. Since the plurality of cleavage grooves 21, 22 and 23 have the same bottom surface area, the plurality of cleavage grooves 21, 22 and 23 may be suppressed from having different depths. According to the method of manufacturing a semiconductor device 12 of the present embodiment, the accuracy in correcting division line 16 toward division reference line 14 by the plurality of cleavage grooves 21, 22 and 23 is further improved, so that cleavage of wafer 11 largely deviated from division reference line 14 may be suppressed.

### Second Embodiment

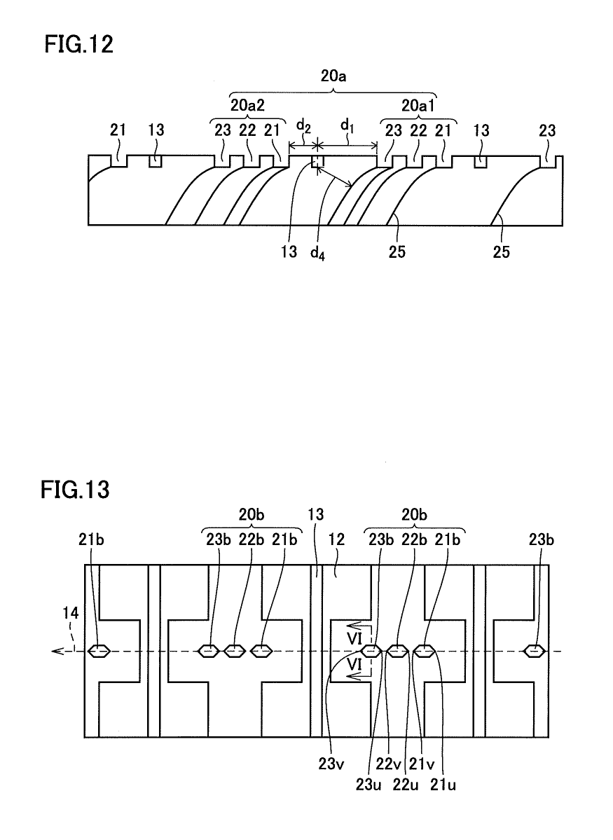

Referring to FIGS. 11 and 12, a method of manufacturing a semiconductor device 12 according to the second embodiment will be hereinafter described. The method of manufacturing a semiconductor device 12 of the present embodiment basically includes the same steps and achieves the same effects as those of the method of manufacturing a semiconductor device 12 of the first embodiment, but is different therefrom mainly in the following points.

A plurality of semiconductor devices 12 each include an active region 13. A plurality of cleavage groove groups 20a include: a first cleavage groove group 20a1 that is adjacent to active region 13 and located on a side of cleavage start point 18 with respect to active region 13; and a second cleavage groove group 20a2 that is adjacent to active region 13 and located on the opposite side of cleavage start point 18 with respect to active region 13. Each of first cleavage groove group 20a1 and second cleavage groove group 20a2 includes a plurality of cleavage grooves 21, 22 and 23. Forming a plurality of cleavage groove groups 20a includes: forming a plurality of cleavage groove groups 20a such that a first distance d₁ between first cleavage groove group 20a1 and active region 13 is greater than a second distance d₂ between second cleavage groove group 20a2 and active region 13.

When semiconductor device 12 is a semiconductor laser or a light emitting diode, level difference 25 lowers the light emitting efficiency of semiconductor device 12. In the manufacturing method of the present embodiment, first distance d₁ between first cleavage groove group 20a1 and active region 13 is greater than second distance d₂ between second cleavage groove group 20a2 and active region 13. Thus, a distance d₄ between level difference 25 and active region 13 in the manufacturing method of the present embodiment (see FIG. 12) is greater than a distance d₃ between level difference 25 and active region 13 in the manufacturing method of the first embodiment (see FIG. 9). According to the method of manufacturing a semiconductor device 12 of the present embodiment, semiconductor device 12 having the improved light emitting efficiency may be manufactured with improved manufacturing yield.

### Third Embodiment

Referring to FIG. 13, a method of manufacturing a semiconductor device 12 according to the third embodiment will be hereinafter described. The method of manufacturing a semiconductor device 12 according to the present embodiment includes basically the same steps as those of the method of manufacturing a semiconductor device 12 in the first embodiment, but is different therefrom mainly in the following points.

The method of manufacturing a semiconductor device 12 of the present embodiment includes forming a plurality of cleavage groove groups 20b. The plurality of cleavage groove groups 20b each include a plurality of cleavage grooves (21b, 22b, 23b). The plurality of cleavage grooves (21b, 22b, 23b) each have the first end that is located on the opposite side of cleavage start point 18 (on the end point F side). This first end has a shape tapered toward the opposite side of cleavage start point 18 (the end point F side). In the method of manufacturing a semiconductor device 12 of the present embodiment, the plurality of cleavage grooves (21b, 22b, 23b) each have the second end that is located on a side of cleavage start point 18 (on the start point S side). The second end may have a shape tapered toward the side of cleavage start point 18 (the start point S side).

Each of the plurality of cleavage grooves (21b, 22b, 23b) in the present embodiment may have a rectangular shape as shown in FIG. 6 in a cross section orthogonal to division reference line 14. Each of the plurality of cleavage grooves (21b, 22b, 23b) may have a V shape in the cross section orthogonal to division reference line 14 as shown in FIGS. 4 and 5.

The effect of the method of manufacturing a semiconductor device 12 of the present embodiment will be hereinafter described. The effect of the method of manufacturing a semiconductor device 12 of the present embodiment mainly has the following effects in addition to the effects similar to those achieved by the method of manufacturing a semiconductor device 12 of the first embodiment.

In the method of manufacturing a semiconductor device 12 of the present embodiment, the plurality of cleavage grooves (21b, 22b, 23b) each have the first end that is located on the opposite side of cleavage start point 18 (on the end point F side). The first end has a shape tapered toward the opposite side of cleavage start point 18 (the end point F side). Stress is generated at the edge portion of each of the plurality of cleavage grooves (21b, 22b, 23b), that is, at the portion of wafer 11 that faces each of the plurality of cleavage grooves (21b, 22b, 23b). This stress concentrates at the tapered end of the first end of each of the plurality of cleavage grooves (21b, 22b, 23b).

When wafer 11 is cleaved, wafer 11 is more likely to be cleaved at the center of the groove width of each of the plurality of cleavage grooves (21b, 22b, 23b) at which the tapered end of the first end of each of the plurality of cleavage grooves (21b, 22b, 23b) is located. Even if each of the plurality of cleavage grooves (21b, 22b, 23b) has a rectangular shape as shown in FIG. 6 in the cross section orthogonal to division reference line 14, division line 16 inclined in the azimuth angle direction with respect to division reference line 14 may be corrected so as to be brought closer to division reference line 14 more accurately at the first end of each of the plurality of cleavage grooves (21b, 22b, 23b). Thus, a plurality of semiconductor devices 12 may be manufactured with a high manufacturing yield.

In the method of manufacturing a semiconductor device 12 of the present embodiment, the plurality of cleavage grooves (21b, 22b, 23b) each have the second end that is located on a side of cleavage start point 18. The second end may have a shape tapered toward the side of cleavage start point 18. Stress is generated at the edge portion of each of the plurality of cleavage grooves (21b, 22b, 23b), that is, at the portion of wafer 11 that faces each of the plurality of cleavage grooves (21b, 22b, 23b). This stress concentrates at the tapered end of the second end of each of the plurality of cleavage grooves (21b, 22b, 23b).

When wafer 11 is cleaved, wafer 11 is more likely to be cleaved at the center of the groove width of each of the plurality of cleavage grooves (21b, 22b, 23b) at which the tapered end of the second end of each of the plurality of cleavage grooves (21b, 22b, 23b) is located. Even if each of the plurality of cleavage grooves (21b, 22b, 23b) has a rectangular shape as shown in FIG. 6 in the cross section orthogonal to division reference line 14, division line 16 inclined in the azimuth angle direction with respect to division reference line 14 may be corrected so as to be brought closer to division reference line 14 more accurately at the second end of each of the plurality of cleavage grooves (21b, 22b, 23b). Thus, a plurality of semiconductor devices 12 may be manufactured with a high manufacturing yield.

### Fourth Embodiment

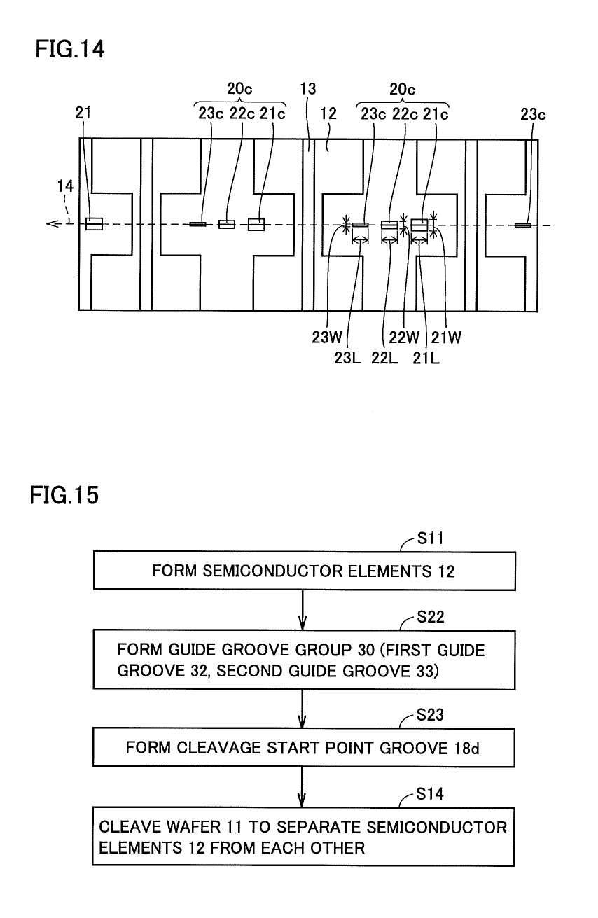

Referring to FIG. 14, a method of manufacturing a semiconductor device 12 according to the fourth embodiment will be hereinafter described. The method of manufacturing a semiconductor device 12 of the present embodiment includes basically the same steps as those of the method of manufacturing a semiconductor device 12 of the first embodiment, but is different therefrom mainly in the following points.

The method of manufacturing a semiconductor device 12 of the present embodiment includes forming a plurality of cleavage groove groups 20c. The plurality of cleavage groove groups 20c each include a plurality of cleavage grooves (21c, 22c, 23c). The plurality of cleavage grooves (21c, 22c, 23c) include a first cleavage groove and a second cleavage groove that are adjacent to each other. The second cleavage groove is located on the opposite side of cleavage start point 18 with respect to the first cleavage groove (on the end point F side).

The second groove width of the second cleavage groove is narrower than the first groove width of the first cleavage groove. For example, cleavage groove 21c and cleavage groove 22c may be regarded as the first cleavage groove and the second cleavage groove, respectively. A groove width 22W of cleavage groove 22 is narrower than a groove width 21W of cleavage groove 21. For example, cleavage groove 22c and cleavage groove 23c may be regarded as the first cleavage groove and the second cleavage groove, respectively. A groove width 23W of cleavage groove 23 is narrower than a groove width 22W of cleavage groove 22. Specifically, cleavage groove group 20c that is located adjacent to active region 13 and located close to cleavage start point 18 relative to active region 13 (on the start point S side) includes a plurality of cleavage grooves (21c, 22c, 23c). Cleavage groove group 20c is configured such that the groove widths (21W, 22W, 23W) of the plurality of cleavage grooves (21c, 22c, 23c) gradually decrease toward active region 13.

Then, the effect of the method of manufacturing a semiconductor device 12 of the present embodiment will be hereinafter described. The effect of the method of manufacturing a semiconductor device 12 of the present embodiment mainly has the following effects in addition to the effects similar to those achieved by the method of manufacturing a semiconductor device 12 of the first embodiment.

In the method of manufacturing a semiconductor device 12 of the present embodiment, the plurality of cleavage grooves (21c, 22c, 23c) include a first cleavage groove and a second cleavage groove that are adjacent to each other. The second cleavage groove is located on the opposite side of cleavage start point 18 with respect to the first cleavage groove (on the end point F side). The second groove width of the second cleavage groove is narrower than the first groove width of the first cleavage groove. Accordingly, the second cleavage groove can correct division line 16 so as to be brought closer to division reference line 14 than by the first cleavage groove. Division line 16 inclined in the azimuth angle direction with respect to division reference line 14 may be corrected so as to be brought closer to division reference line 14 more accurately between the plurality of cleavage groove groups 20c.

### Fifth Embodiment

Referring to FIGS. 15 to 21 and 23, a method of manufacturing a semiconductor device 12 according to the fifth embodiment will be hereinafter described.

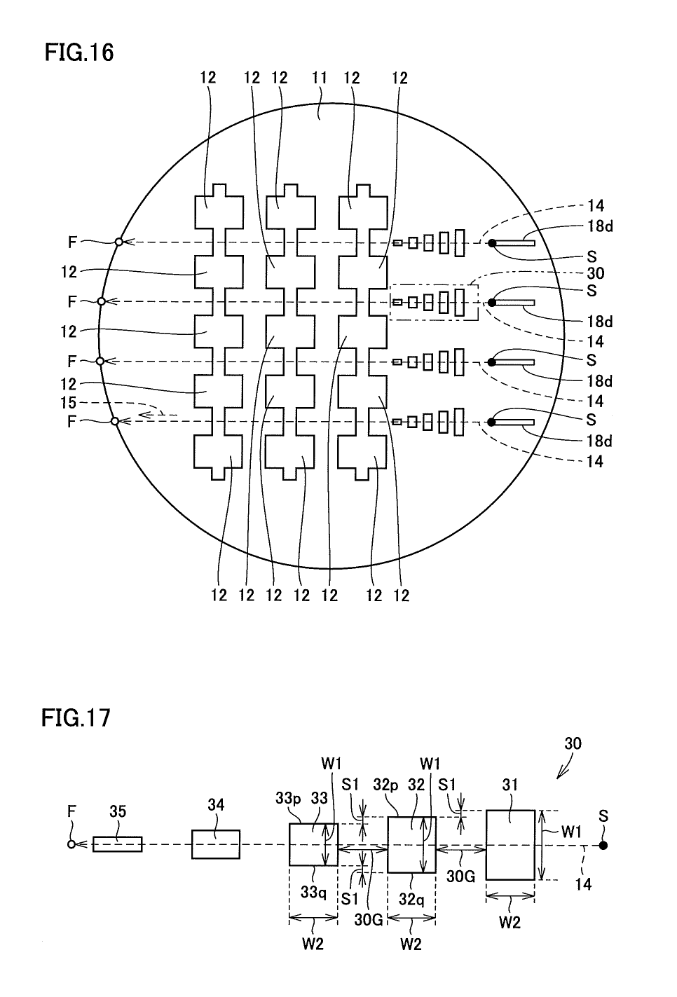

Referring to FIGS. 15 and 16, the method of manufacturing a semiconductor device 12 according to the present embodiment includes forming a plurality of semiconductor devices 12 in each of one region and the other region that sandwich division reference line 14 on wafer 11 (S11). When cleaving a wafer 11 (S14) after forming a plurality of semiconductor devices 12 (S11), wafer 11 is cleaved in the arrow direction of division reference line 14. Wafer 11 is cleaved from a start point S shown by a black circle toward an end point F shown by a white circle. In the present embodiment, start point S and end point F are located on division reference line 14. In the present embodiment, division reference line 14 and cleavage line 15 are parallel to each other.

The material of wafer 11 is not particularly limited, but may be indium phosphide (InP), for example. The plurality of semiconductor devices 12 may be arranged in a matrix form. The plurality of semiconductor devices 12 include a semiconductor layer, an insulating layer and an electrode, for example. By the same method as that in the first embodiment, the plurality of semiconductor devices 12 may be formed on wafer 11. In the present embodiment, each of the plurality of semiconductor devices 12 is formed to have a pair of side surfaces that are almost parallel to division reference line 14. In the present embodiment, semiconductor device 12 is a light emitting diode, and includes an active region 13. The plurality of semiconductor devices 12 are divided to obtain active regions 13. From each of active regions 13 in the plurality of semiconductor devices 12, light is emitted. In the present embodiment, the direction in which each active region 13 extends is orthogonal to division reference line 14 and cleavage line 15. Semiconductor device 12 is not limited to a light emitting diode, but may be a transistor having a vertical structure or a horizontal structure, for example.

Referring to FIGS. 15 to 17, the method of manufacturing a semiconductor device 12 of the present embodiment includes forming a guide groove group 30 on wafer 11 (S22). One guide groove group 30 may be formed for one division reference line 14. Forming a plurality of guide groove groups 30 (S22) may be performed simultaneously with forming a device separation groove (not shown) in semiconductor device 12. Thereby, the time taken to manufacture semiconductor device 12 may be shortened.

Each of the plurality of guide groove groups 30 includes a plurality of guide grooves (a first guide groove 32, a second guide groove 33, and guide grooves 31, 34 and 35). The plurality of guide grooves (first guide groove 32, second guide groove 33, guide grooves 31, 34 and 35) include first guide groove 32, second guide groove 33, and guide grooves 31, 34 and 35. Second guide groove 33 is arranged so as to be distanced away from first guide groove 32 toward end point F. Guide groove 31 is arranged so as to be distanced away from first guide groove 32 toward start point S. Guide groove 34 is arranged so as to be distanced away from second guide groove 33 toward end point F. Guide groove 35 is arranged so as to be distanced away from guide groove 34 toward end point F. Each of first guide groove 32 and second guide groove 33 is arranged over one region and the other region that sandwich division reference line 14. In other words, first guide groove 32 has a first side surface 32p in one region and a third side surface 32q in the other region. Second guide groove 33 has a second side surface 33p in one region and a fourth side surface 33q in the other region.

Each of the plurality of guide grooves (first guide groove 32, second guide groove 33, and guide grooves 31, 34 and 35) has a groove width W1 extending in the direction perpendicular to division reference line 14 and a groove length W2 extending in the direction parallel to division reference line 14. The plurality of guide grooves (first guide groove 32, second guide groove 33, guide grooves 31, 34 and 35) are arranged along division reference line 14 so as to be spaced at a groove distance 30G from each other. Start point S is located close to a cleavage start point groove 18d relative to guide groove group 30. Start point S is located within groove width W1 of guide groove 31 in the direction perpendicular to division reference line 14. Specifically, start point S may be located at the center of groove width W1 of each of the plurality of guide grooves (first guide groove 32, second guide groove 33, guide grooves 31, 34 and 35) in the direction perpendicular to division reference line 14.

A groove step distance S1 is defined as a difference between (i) a distance between division reference line 14 and a side surface (for example, first side surface 32p), which is farther away from division reference line 14, of the side surfaces of the guide groove (for example, first guide groove 32) along division reference line 14 and (ii) a distance between division reference line 14 and a side surface (for example, second side surface 33p), which is farther away from division reference line 14, of the side surfaces of the adjoining guide groove (for example, second guide groove 33) extending in division reference line 14. Specifically, groove step distance S1 is defined as a difference between (i) a distance between first side surface 32p and division reference line 14 and (ii) a distance between second side surface 33p and division reference line 14. The side surface along division reference line 14 does not have to be a side surface that is strictly parallel to division reference line 14. In the present embodiment, first side surface 32p and third side surface 32q of first guide groove 32 sandwich division reference line 14. Division reference line 14 passes through the center of first guide groove 32 in the width direction. Second side surface 33p and fourth side surface 33q of second guide groove 33 sandwich division reference line 14. Division reference line 14 passes through the center of second guide groove 33 in the width direction. Groove step distance S1 is half of the difference between groove widths W1 of the guide grooves adjacent to each other.

For example, when wafer 11 is made of an InP material and has a thickness of 100 μm, it is preferable that groove step distance S1 is about 5 μm or less, groove distance 30G is about 10 μM to about 100 μm, groove width W1 is about 10 μm to about 100 μm, and the depth of the guide groove (first guide groove 32, second guide groove 33, guide grooves 31, 34 and 35) is about 5 μm or more. Groove width W1, groove length W2, groove distance 30G, and groove step distance S1 may be set as appropriate in accordance with the size and the thickness of wafer 11, the number of semiconductor devices 12 formed in wafer 11, and the like.

First side surface 32p of first guide groove 32 and second side surface 33p of second guide groove 33 are located in one region of the regions sandwiching division reference line 14. First side surface 32p of first guide groove 32 and second side surface 33p of second guide groove 33 each extend along division reference line 14. First side surface 32p of first guide groove 32 and second side surface 33p of second guide groove 33 each extend in the direction from start point S to end point F. In the present embodiment, since start point S is located on division reference line 14, the side surface along division reference line 14 extends in the direction from start point S to end point F.

Third side surface 32q of first guide groove 32 that faces first side surface 32p is located in the other region of the regions sandwiching division reference line 14. Fourth side surface 33q of second guide groove 33 that faces second side surface 33p is located in the other region of the regions that sandwich division reference line 14. Third side surface 32q of first guide groove 32 and fourth side surface 33q of second guide groove 33 each extend along division reference line 14. First side surface 32p and third side surface 32q of first guide groove 32 sandwich division reference line 14. Second side surface 33p and fourth side surface 33q of second guide groove 33 sandwich division reference line 14.

As shown in FIG. 17, guide groove group 30 includes a plurality of guide grooves (first guide groove 32, second guide groove 33, guide grooves 31, 34 and 35). First guide groove 32 may be the second guide groove from start point S (the second guide groove from the right side in the figure). Second guide groove 33 may be the third guide groove from start point S. The second guide groove 34 from end point F (the second guide groove from the left side in the figure) may be regarded as the first guide groove, and guide groove 35 closest to end point F (located on the leftmost side in the figure) may be regarded as the second guide groove. Guide groove 31 closest to start point S (located on the rightmost side in the figure) may be regarded as the first guide groove, and the second guide groove (32) from start point S (the second guide groove from the right side in the figure) may be regarded as the second guide groove. The guide grooves adjacent to each other may be regarded as the first guide groove and the second guide groove, and these two guide grooves may be arranged repeatedly, thereby forming a guide groove group 30 including a plurality of guide grooves (first guide groove 32, second guide groove 33, guide grooves 31, 34 and 35).

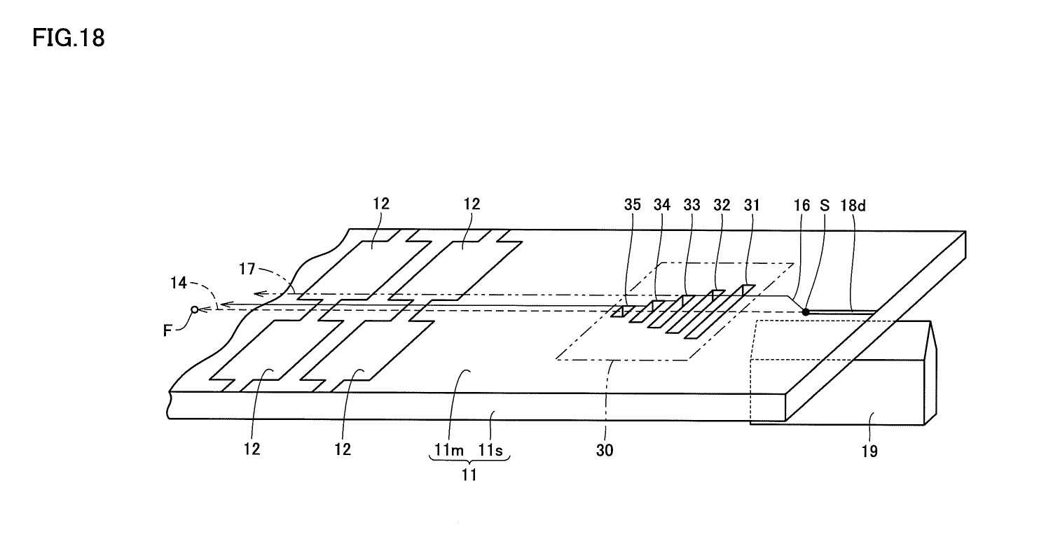

Referring to FIGS. 17 and 18, an explanation will be hereinafter given with regard to groove width W1 of guide groove 31 that is closest to start point S (a guide groove with which division line 16 first comes in contact, which corresponds to a groove located on the rightmost side in FIG. 17). In the present embodiment, groove width W1 of the guide groove closest to start point S is longer than the length that is preferably twice as large as the maximum distance from division reference line 14 to division line 16 in the method of manufacturing a semiconductor device 12 of the comparative example in which wafer 11 is cleaved without forming guide groove group 30. For example, if the maximum distance from division reference line 14 to division line 16 in the method of manufacturing a semiconductor device 12 of the comparative example is about 15 μm or less, groove width W1 of guide groove 31 is preferably about 30 μm or more in the case where division reference line 14 passes through the center of groove width W1 of guide groove 31 as shown in FIG. 17.

The plurality of guide grooves (first guide groove 32, second guide groove 33, guide grooves 31, 34 and 35) may be formed by etching wafer 11 using a mask having an opening formed by the photolithography process. Specifically, a silicon dioxide (SiO₂) film is formed on wafer 11 by the sputtering method, the plasma chemical vapor deposition (CVD) method, or the like. A resist is formed on the SiO₂ film. The resist is provided with an opening using the photolithography process. The resist having an opening provided therein is used to dry etch the SiO₂ film, thereby providing an opening in the SiO₂ film. When dry etching is performed, gas made of compounds such as carbon, hydrogen, and fluoride may be used. Wafer 11 is etched using the SiO₂ film having an opening formed therein as a mask. This etching of wafer 11 may be performed, for example, by dry etching such as inductively coupled reactive ion etching (ICP-RIE). Thus, the plurality of guide grooves (first guide groove 32, second guide groove 33, guide grooves 31, 34 and 35) may be formed by etching wafer 11.

In the method of manufacturing a semiconductor device 12 of the present embodiment, forming a plurality of guide grooves (first guide groove 32, second guide groove 33, guide grooves 31, 34 and 35) may also include further performing wet etching after dry etching wafer 11. It is to be noted that wet etching needs to be performed so as not to influence the characteristics of the plurality of semiconductor devices 12 that have already been formed before forming the plurality of guide grooves (first guide groove 32, second guide groove 33, guide grooves 31, 34 and 35).

Referring to FIGS. 15 and 16, the method of manufacturing a semiconductor device 12 of the present embodiment may further include forming a cleavage start point groove 18d (S23). Cleavage start point groove 18d is provided on the side of guide groove group 30 close to start point S. Cleavage start point groove 18d is formed, for example, by scribing wafer 11 along division reference line 14 using a needle made of a hard material such as a diamond. Either forming a guide groove group 30 (S22) or forming a cleavage start point groove 18d (S23) may be performed first.

The method of manufacturing a semiconductor device 12 according to the present embodiment further includes grinding wafer 11 so as to have a prescribed thickness after forming a guide groove group 30 (S22) and forming a cleavage start point groove 18d (S23). When each of the plurality of semiconductor devices 12 requires a backside electrode, the method of manufacturing a semiconductor device 12 of the present embodiment may further include forming a backside electrode on the backside surface of wafer 11.

Referring to FIGS. 15 to 21, the method of manufacturing a semiconductor device 12 of the present embodiment further includes cleaving wafer 11 to separate the plurality of semiconductor devices 12 from each other (S14). Specifically, as shown in FIG. 18, blade 19 is pressed against wafer 11 from the backside of wafer 11 to apply a load to wafer 11. Wafer 11 is cleaved from cleavage start point groove 18d along cleavage line 15. As shown in FIGS. 16 and 17, wafer 11 is cleaved along division reference line 14 from start point S shown by a black circle toward end point F shown by a white circle. In FIG. 18, for example, when wafer 11 has main surface 11m of a (100) plane, cleavage plane 11s is a (0-1-1) plane, and wafer 11 is cleaved from cleavage start point groove 18d in the [01-1] direction or the [0-11] direction.

When cleavage start point groove 18d is formed by scribing, cracks extending in various directions are formed around cleavage start point groove 18d. If a plurality of guide grooves (first guide groove 32, second guide groove 33, guide grooves 31, 34 and 35) are not provided, wafer 11 may be divided along a division line 17 in the case of no grooves (see FIG. 18) deviated from division reference line 14 due to these cracks. On the other hand, the method of manufacturing a semiconductor device 12 according to the present embodiment includes forming a guide groove group 30 including a plurality of guide grooves (first guide groove 32, second guide groove 33, guide grooves 31, 34 and 35) on wafer 11 (S22). Guide groove group 30 including a plurality of guide grooves (first guide groove 32, second guide groove 33, guide grooves 31, 34 and 35) serves to correct division line 16 deviated from division reference line 14 due to these cracks (see FIG. 18) so as to be brought closer to division reference line 14.

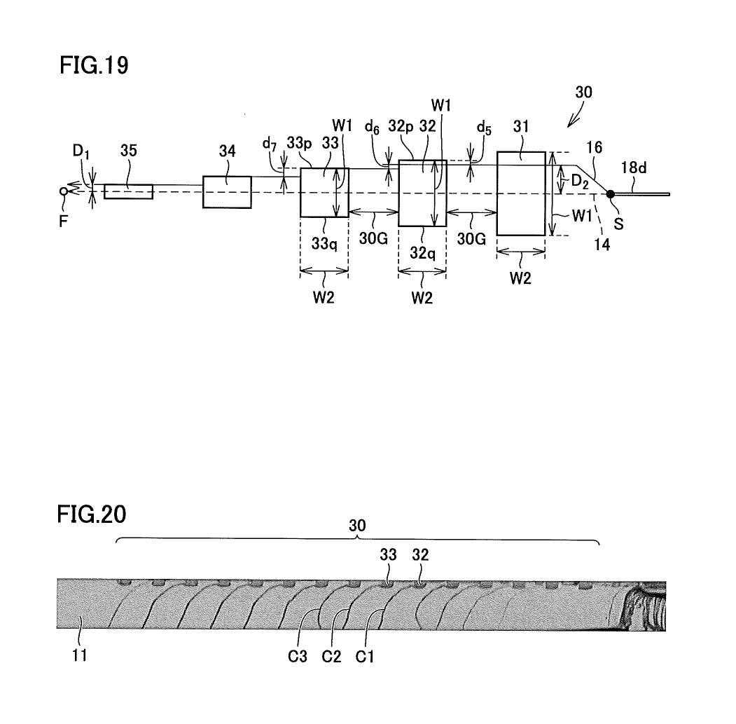

Referring to FIGS. 19 and 20, a detailed explanation will be given with regard to correction of division line 16 by guide groove group 30 including a plurality of guide grooves (first guide groove 32, second guide groove 33, guide grooves 31, 34 and 35). Division line 16 deviates from cleavage start point groove 18d toward first side surface 32p of first guide groove 32, for example, as shown in FIG. 19. In this case, division line 16 extends along cleavage line 15 parallel to division reference line 14 at a position deviated by several μm to several tens μm from division reference line 14.

Division line 16 contacts guide groove 31 located closest to start point S (the rightmost guide groove 31 in FIG. 19). When the extension line of division line 16 in guide groove 31 exists inside the guide groove (first guide groove 32) adjacent to guide groove 31 in the cleavage direction (the direction from start point S to end point F), division line 16 is not corrected by guide groove 31. When the extension line of division line 16 in guide groove 31 is located close to division reference line 14 relative to first side surface 32p of first guide groove 32, division line 16 is not corrected in the direction of division reference line 14 by guide groove 31. Specifically, as shown in FIG. 19, when the extension line of division line 16 in guide groove 31 is located inside first guide groove 32 by a distance d₅, division line 16 is not corrected in the direction of division reference line 14 by guide groove 31.

Division line 16 that is not corrected by guide groove 31 contacts first guide groove 32. When the extension line of division line 16 in first guide groove 32 exists outside the guide groove (second guide groove 33) adjacent to first guide groove 32 in the cleavage direction, division line 16 is corrected toward division reference line 14 by first guide groove 32. When the extension line of division line 16 in first guide groove 32 is farther away from division reference line 14 relative to second side surface 33p of second guide groove 33, division line 16 is corrected toward division reference line 14 by first guide groove 32. Specifically, as shown in FIG. 19, when the extension line of division line 16 in first guide groove 32 is located outside second guide groove 33 by a distance d₆, division line 16 is corrected toward division reference line 14 at the end of first guide groove 32 in the cleavage direction (on the end point F side). Division line 16 is corrected toward division reference line 14 by a distance d₇ at the end of second guide groove 33 in the cleavage direction (on the end point F side) in the same manner as with first guide groove 32. This correction is repeated by a plurality of guide grooves (for example, first guide groove 32, second guide groove 33, guide groove 34), thereby bringing division line 16 to gradually closer to division reference line 14.

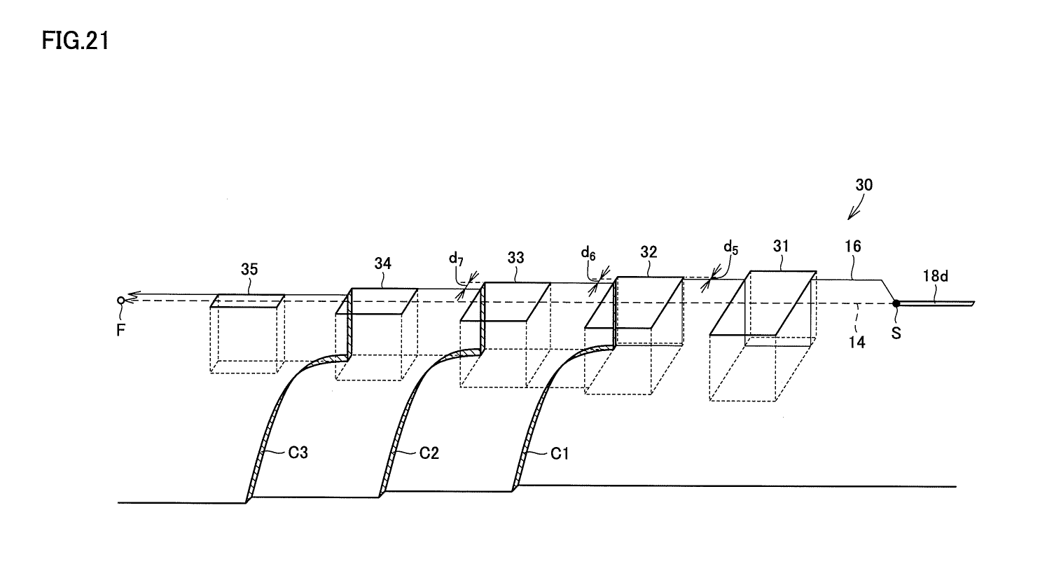

As shown in FIG. 20, guide groove group 30 has fifteen guide grooves. As shown in FIGS. 20 and 21, when division line 16 is corrected at the end of each of the plurality of guide grooves (for example, first guide groove 32, second guide groove 33, guide groove 34) in the cleavage direction (on the end point F side), level differences C1, C2 and C3 are formed on division line 16 and the division plane. Level differences C1, C2 and C3 extend (i) in the direction from the plurality of guide grooves (for example, first guide groove 32, second guide groove 33, guide groove 34) toward the opposite side of cleavage start point groove 18d from cleavage start point groove 18d (the direction from start point S to end point F) and (ii) in the direction from main surface 11m of wafer 11 to the backside surface of wafer 11. The size of each of level differences C1, C2 and C3 corresponds to the correction amount of division line 16 and the division plane in each of the plurality of guide grooves (for example, first guide groove 32, second guide groove 33, guide groove 34). Each of level differences C1, C2 and C3 is formed from main surface 11m of wafer 11 to the backside surface of wafer 11. By the plurality of guide grooves (for example, first guide groove 32, second guide groove 33, guide groove 34), the division plane deviated from division reference line 14 is corrected also on the backside surface of wafer 11.

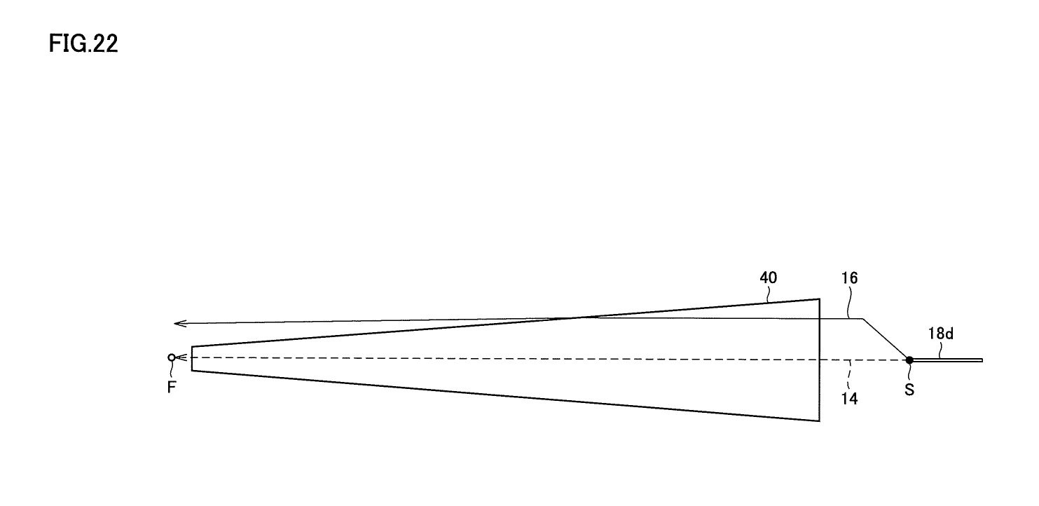

Referring to FIG. 22, in the method of manufacturing a semiconductor device 12 according to the comparative example, in place of guide groove group 30 of the present embodiment, one tapered groove 40 is provided in wafer 11 for one division reference line 14. The direction in which the groove width of tapered groove 40 becomes narrower corresponds to the cleavage direction (toward end point F). Tapered groove 40 is shaped to have a groove width that converges toward end point F. In the method of manufacturing a semiconductor device 12 according to the comparative example, when division line 16 deviated from division reference line 14 contacts tapered groove 40, division line 16 is slightly corrected along the side surface of tapered groove 40. However, division line 16 is not continuously corrected along the side surface of tapered groove 40 by tapered groove 40.

On the other hand, in the method of manufacturing a semiconductor device 12 according to the present embodiment, a plurality of guide grooves (first guide groove 32, second guide groove 33, guide grooves 31, 34 and 35) are provided in wafer 11 for one division reference line 14. Wafer 11 does not exist inside the plurality of guide grooves (first guide groove 32, second guide groove 33, guide grooves 31, 34 and 35), whereas wafer 11 exists around the circumference of each of the plurality of guide grooves (first guide groove 32, second guide groove 33, guide grooves 31, 34 and 35). Accordingly, stress is generated at an edge portion of each of the plurality of guide grooves (first guide groove 32, second guide groove 33, guide grooves 31, 34 and 35), that is, at the portion of wafer 11 that faces each of the plurality of guide grooves (first guide groove 32, second guide groove 33, guide grooves 31, 34 and 35). At the first end on the start point S side and the second end on the end point F side in each of the plurality of guide grooves (first guide groove 32, second guide groove 33, guide grooves 31, 34 and 35), stress is generated not only in the cleavage direction but also in the direction perpendicular to the cleavage direction (that is, the width direction of the guide groove).

Due to this stress, division line 16 is corrected toward division reference line 14 at the second end of each of the plurality of guide grooves (for example, first guide groove 32, second guide groove 33, guide grooves 34 and 35) in the cleavage direction. Also, in the method of manufacturing a semiconductor device 12 of the present embodiment, a plurality of guide grooves (first guide groove 32, second guide groove 33, guide grooves 31, 34 and 35) are provided in wafer 11 for one division reference line 14. Accordingly, division line 16 deviated from division reference line 14 may be corrected at a plurality of portions. Thus, the plurality of guide grooves (first guide groove 32, second guide groove 33, guide grooves 31, 34 and 35) can improve the accuracy in correcting division line 16 toward division reference line 14.

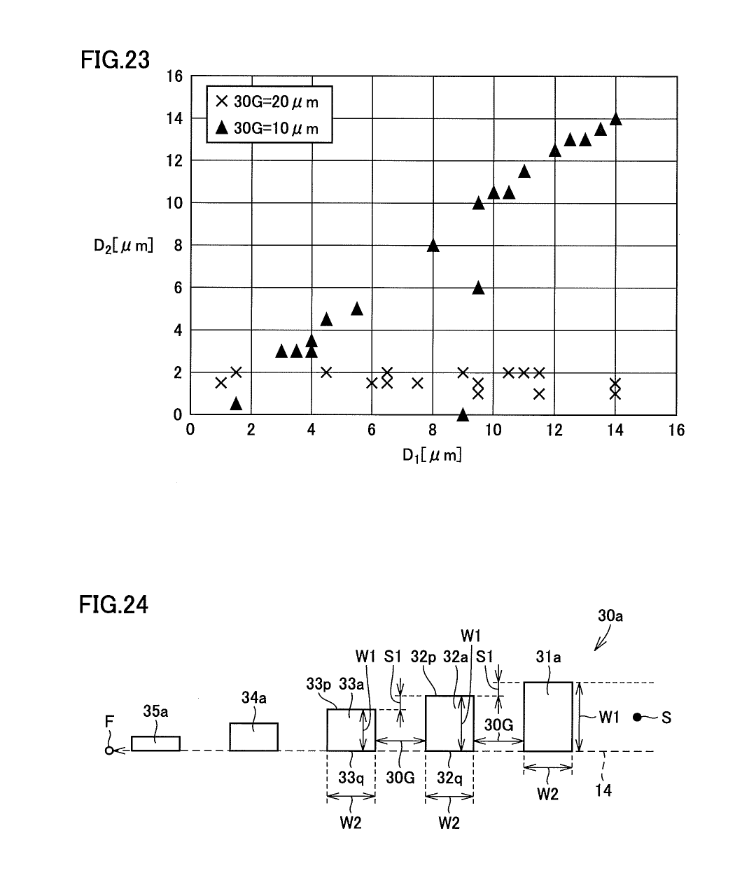

Referring to FIG. 23, it is preferable that groove distance 30G is as large as possible. The horizontal axis in FIG. 23 shows a distance D₁ [μm] between division reference line 14 and division line 16 before this division line 16 contacts the plurality of guide grooves (first guide groove 32, second guide groove 33, guide grooves 31, 34 and 35). The vertical axis in FIG. 23 shows a distance D₂ [μm] between division reference line 14 and division line 16 after this division line 16 is corrected by the plurality of guide grooves (first guide groove 32, second guide groove 33, guide grooves 31, 34 and 35).

As shown in FIG. 23, it turns out that distance D₂ is closer to 0 μm when groove distance 30G between the plurality of guide grooves (first guide groove 32, second guide groove 33, guide grooves 31, 34 and 35) is set at 20 μm than when groove distance 30G between the plurality of guide grooves (first guide groove 32, second guide groove 33, guide grooves 31, 34 and 35) is set at 10 μm. This tendency remarkably appears when there is a large distance D₁ between division reference line 14 and division line 16 before this division line 16 contacts the plurality of guide grooves (first guide groove 32, second guide groove 33, guide grooves 31, 34 and 35). For example, when groove distance 30G between the plurality of guide grooves (first guide groove 32, second guide groove 33, guide grooves 31, 34 and 35) is set at 20 μm, guide groove group 30 including the plurality of guide grooves (first guide groove 32, second guide groove 33, guide grooves 31, 34 and 35) can decrease distance D₁ of 14 μm to distance D₂ of 2 μm. Groove distance 30G between the plurality of guide grooves (first guide groove 32, second guide groove 33, guide grooves 31, 34 and 35) is 20 μm or more, which enhances the effect of correcting division line 16 toward division reference line 14 by the plurality of guide grooves (first guide groove 32, second guide groove 33, guide grooves 31, 34 and 35).

On the other hand, when groove distance 30G between the plurality of guide grooves (first guide groove 32, second guide groove 33, guide grooves 31, 34 and 35) is too large, the number of guide grooves decreases. Accordingly, the effect of correcting division line 16 toward division reference line 14 by the plurality of guide grooves (first guide groove 32, second guide groove 33, guide grooves 31, 34 and 35) becomes similar to that achieved when the plurality of guide grooves (first guide groove 32, second guide groove 33, guide grooves 31, 34 and 35) are not provided. Thus, it is preferable that groove distance 30G between the plurality of guide grooves (first guide groove 32, second guide groove 33, guide grooves 31, 34 and 35) is about 10 μm or more and about several hundred μm or less. In FIG. 23, each of the plurality of guide grooves (first guide groove 32, second guide groove 33, guide grooves 31, 34 and 35) has a groove length W2 of 20 μm.

As having already been described, in the method of manufacturing a semiconductor device 12 of the present embodiment, forming a guide groove group 30 including a plurality of guide grooves (first guide groove 32, second guide groove 33, guide grooves 31, 34 and 35) (S22) may include further performing wet etching after dry etching wafer 11. When wafer 11 is wet etched, each of the plurality of guide grooves (first guide groove 32, second guide groove 33, guide grooves 31, 34 and 35) is configured to have a bottom surface formed in an inverted triangular cross-sectional shape that has an acute angle toward the center of the groove width of each of the plurality of guide grooves (first guide groove 32, second guide groove 33, guide grooves 31, 34 and 35). The plurality of guide grooves (first guide groove 32, second guide groove 33, guide grooves 31, 34 and 35) each having an inverted triangular cross-sectional shape can correct division line 16 toward the center of the groove width of each of the plurality of guide grooves (first guide groove 32, second guide groove 33, guide grooves 31, 34 and 35). The plurality of guide grooves (first guide groove 32, second guide groove 33, guide grooves 31, 34 and 35) each having an inverted triangular cross-sectional shape can further more accurately correct division line 16 deviated from division reference line 14.

In the above description, as shown in FIG. 19, an explanation has been given with regard to correction of division line 16 toward division reference line 14 in the case where division line 16 deviates from cleavage start point groove 18d in the direction of first side surface 32p of first guide groove 32. In contrast to FIG. 19, however, division line 16 may deviate from cleavage start point groove 18d in the direction of third side surface 32q of first guide groove 32. Also in this case, first guide groove 32 and second guide groove 33 correct division line 16 toward division reference line 14. In other words, when division line 16 deviates from cleavage start point groove 18d in the direction of third side surface 32q of first guide groove 32, division line 16 is not corrected by guide groove 31 located closest to start point S. Division line 16 is corrected toward division reference line 14 at the end of third side surface 32q of first guide groove 32 in the cleavage direction (on the end point F side). Division line 16 is corrected toward division reference line 14 at the end of fourth side surface 33q of second guide groove 33 in the cleavage direction (on the end point F side).

The effect of the method of manufacturing a semiconductor device 12 of the present embodiment will be hereinafter described.

In the method of manufacturing a semiconductor device 12 of the present embodiment, when wafer 11 is cleaved to separate the plurality of semiconductor devices 12 from each other, the plurality of guide grooves (first guide groove 32, second guide groove 33, guide grooves 31, 34 and 35) correct division line 16 toward division reference line 14. According to the method of manufacturing a semiconductor device 12 of the present embodiment, cleavage of wafer 11 largely deviated from division reference line 14 can be suppressed. Furthermore, in the method of manufacturing a semiconductor device 12 of the present embodiment, even if division line 16 is deviated from division reference line 14 and cleavage start point groove 18d toward either of a pair of side surfaces (first side surface 32p and third side surface 32q) of first guide groove 32 along division reference line 14, division line 16 may be corrected toward division reference line 14.

Forming a plurality of guide grooves (first guide groove 32, second guide groove 33, guide grooves 31, 34 and 35) may be performed simultaneously with forming a device separation groove (not shown) in semiconductor device 12. Thereby, the manufacturing time of semiconductor device 12 may be shortened.

### Sixth Embodiment

Referring to FIG. 24, the method of manufacturing a semiconductor device 12 of the sixth embodiment will be hereinafter described. The method of manufacturing a semiconductor device 12 of the present embodiment includes basically the same steps as those of the method of manufacturing a semiconductor device 12 of the fifth embodiment, but is different therefrom mainly in the following points. The present embodiment is different from the fifth embodiment in arrangement of the plurality of guide grooves (a first guide groove 32a, a second guide groove 33a, guide grooves 31a, 34a, and 35a) included in a guide groove group 30a, and particularly in positions of the plurality of guide grooves (first guide groove 32a, second guide groove 33a, guide grooves 31a, 34a, and 35a) relative to division reference line 14.

In the method of manufacturing a semiconductor device 12 of the present embodiment, one of the side surfaces of each of the plurality of guide grooves (first guide groove 32a, second guide groove 33a, guide grooves 31a, 34a, and 35a) included in guide groove group 30a formed in wafer 11 is located on division reference line 14. Specifically, third side surface 32q of first guide groove 32a and fourth side surface 33q of second guide groove 33a are located on division reference line 14. The difference between: (i) the distance between division reference line 14 and the side surface (for example, first side surface 32p), which is farther away from division reference line 14, of the side surfaces of each of the plurality of guide grooves (for example, first guide groove 32a) along division reference line 14; and (ii) the distance between division reference line 14 and the side surface (for example, second side surface 33p), which is farther away from division reference line 14, of the side surfaces of the adjoining guide groove (for example, second guide groove 33) along division reference line 14 is defined as a groove step distance S1. Groove step distance S1 in the present embodiment is twice as large as groove step distance S1 in the fifth embodiment.

The effect of the method of manufacturing a semiconductor device 12 of the present embodiment will be hereinafter described. The effect of the method of manufacturing a semiconductor device 12 of the present embodiment mainly has the following effects in addition to the effects similar to those achieved by the method of manufacturing a semiconductor device 12 of the fifth embodiment.

When division line 16 deviates from start point S in the direction of first side surface 32p of first guide groove 32a, guide groove group 30a of the present embodiment corrects division line 16 toward division reference line 14 in the same manner as with guide groove group 30 of the fifth embodiment. According to the method of manufacturing a semiconductor device 12 of the present embodiment, cleavage of wafer 11 largely deviated from division reference line 14 can be suppressed. Furthermore, when division line 16 is corrected toward division reference line 14 by the plurality of guide grooves (first guide groove 32a, second guide groove 33a, guide grooves 31a, 34a, and 35a) and brought into contact with the side surfaces (for example, third side surface 32q and fourth side surface 33q) of the plurality of guide grooves (first guide groove 32a, second guide groove 33a, guide grooves 31a, 34a, and 35a) on division reference line 14, division line 16 extends along the side surfaces (for example, third side surface 32q and fourth side surface 33q) of the plurality of guide grooves (first guide groove 32a, second guide groove 33a, guide grooves 31a, 34a, and 35a) on division reference line 14.

### Seventh Embodiment

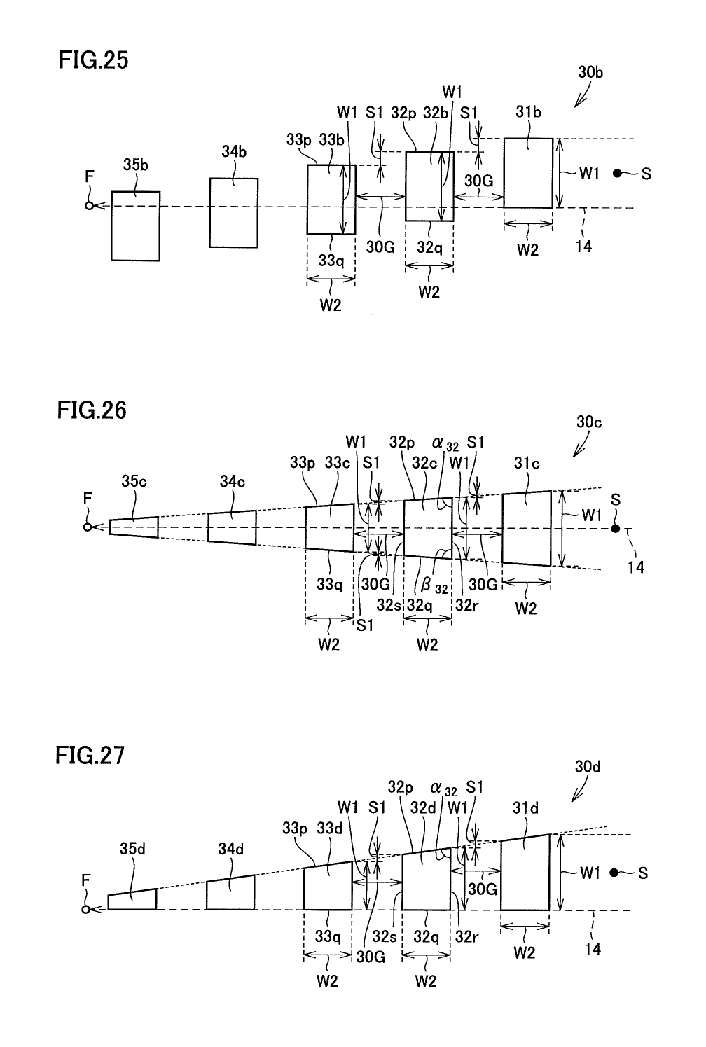

Referring to FIG. 25, the method of manufacturing a semiconductor device 12 according to the seventh embodiment will be hereinafter described. The method of manufacturing a semiconductor device 12 according to the present embodiment includes basically the same steps as those of the method of manufacturing a semiconductor device 12 of the fifth embodiment, but is different therefrom mainly in the following points.

The plurality of guide grooves (first guide groove 32b, second guide groove 33b, guide grooves 31b, 34b, and 35b) included in guide groove group 30b formed on wafer 11 has the same bottom surface area. For example, first guide groove 32b has the same bottom surface area as that of second guide groove 33b. One side surface, which extends along division reference line 14, of the side surfaces of guide groove 31b closest to start point S is located on division reference line 14. Third side surface 32q of first guide groove 32b and fourth side surface 33q of second guide groove 33b are located in the other region of two regions that sandwich division reference line 14. One side surface, which extends along division reference line 14, of the side surfaces of each of guide grooves 34b and 35b closer to end point F relative to second guide groove 33b is located in the other region of two regions that sandwich division reference line 14.

Groove step distance S1 in the method of manufacturing a semiconductor device 12 of the present embodiment may be set as appropriate in accordance with the size and the thickness of wafer 11, the number of semiconductor devices 12 formed in wafer 11, groove width W1, groove length W2, groove distance 30G, and the like.

The effect of the method of manufacturing a semiconductor device 12 of the present embodiment will be hereinafter described. The effect of the method of manufacturing a semiconductor device 12 of the present embodiment mainly has the following effects in addition to the effects similar to those achieved by the method of manufacturing a semiconductor device 12 of the fifth embodiment.

When division line 16 deviates from start point S in the direction of first side surface 32p of first guide groove 32b, guide groove group 30b of the present embodiment corrects division line 16 toward division reference line 14 in the same manner as with guide groove group 30 in the fifth embodiment. According to the method of manufacturing a semiconductor device 12 of the present embodiment, cleavage of wafer 11 largely deviated from division reference line 14 can be suppressed. Furthermore, when division line 16 is corrected toward division reference line 14 by the plurality of guide grooves (first guide groove 32b, second guide groove 33b, guide grooves 31b, 34b, and 35b) and brought into contact with division reference line 14, division line 16 extends along division reference line 14.

In the method of manufacturing a semiconductor device 12 of the present embodiment, the plurality of guide grooves (first guide groove 32b, second guide groove 33b, guide grooves 31b, 34b, and 35b) have the same bottom surface area. Accordingly, the mask openings having the same area are applied when wafer 11 is etched to form a plurality of guide grooves (first guide groove 32b, second guide groove 33b, guide grooves 31b, 34b, and 35b). When the plurality of guide grooves (first guide groove 32b, second guide groove 33b, guide grooves 31b, 34b, and 35b) included in guide groove group 30b are simultaneously formed, the plurality of guide grooves (first guide groove 32b, second guide groove 33b, guide grooves 31b, 34b, and 35b) are suppressed from having different depths. According to the method of manufacturing a semiconductor device 12 of the present embodiment, the accuracy in correcting division line 16 toward division reference line 14 by the plurality of guide grooves (first guide groove 32b, second guide groove 33b, guide grooves 31b, 34b, and 35b) is further improved, so that cleavage of wafer 11 largely deviated from division reference line 14 may be further suppressed.

On the other hand, if the mask openings have different areas, a plurality of guide grooves having different depths are to be formed. If the guide grooves are deep, wafer 11 is more likely to break. If the guide grooves are shallow, division line 16 is less likely to be corrected.

### Eighth Embodiment

Referring to FIG. 26, a method of manufacturing a semiconductor device 12 according to the eighth embodiment will be hereinafter described. The method of manufacturing a semiconductor device 12 according to the present embodiment includes basically the same steps as those of the method of manufacturing a semiconductor device 12 of the fifth embodiment, but is different therefrom mainly in the following points.

The method of manufacturing a semiconductor device 12 according to the present embodiment is different from the method of manufacturing a semiconductor device 12 of the fifth embodiment in shapes of the plurality of guide grooves (first guide groove 32c, second guide groove 33c, guide grooves 31c, 34c, and 35c) included in guide groove group 30c. Each of the plurality of guide grooves (first guide groove 32, second guide groove 33, guide grooves 31, 34 and 35) of the fifth embodiment has a rectangular shape when seen in a plan view of main surface 11m of wafer 11 (see FIG. 18). On the other hand, each of the plurality of guide grooves (first guide groove 32c, second guide groove 33c, guide grooves 31c, 34c, and 35c) of the present embodiment has a trapezoidal shape when seen in a plan view of main surface 11m of wafer 11 (see FIG. 18).

With reference to first guide groove 32c as an example, the shapes of the plurality of guide grooves (first guide groove 32c, second guide groove 33c, guide grooves 31c, 34c, and 35c) of the present embodiment will be hereinafter described. First side surface 32p and third side surface 32q each extend along division reference line 14. In the present embodiment, the side surface along division reference line 14 (for example, first side surface 32p and third side surface 32q) does not need to be strictly parallel to division reference line 14, like the fifth embodiment. The side surface along division reference line 14 does not need to be located on division reference line 14.

In the present embodiment, the side surface along division reference line 14 corresponds to a side surface, which forms an acute angle with division reference line 14, of the side surfaces included in each of the plurality of guide grooves (first guide groove 32c, second guide groove 33c, guide grooves 31c, 34c, and 35c). Among the side surfaces connecting first side surface 32p and third side surface 32q, the side surface closer to start point S is a first connection side surface 32r, and the side surface closer to end point F is a second connection side surface 32s. An angle α₃₂ of first guide groove 32c formed between first side surface 32p and first connection side surface 32r is defined at 45 degrees or more and less than 90 degrees, and preferably at 80 degrees or more and less than 90 degrees. An angle β₃₂ of first guide groove 32c formed between third side surface 32q and first connection side surface 32r is defined at 45 degrees or more and less than 90 degrees, and preferably at 80 degrees or more and less than 90 degrees.

When seen in a plan view of main surface 11m of wafer 11 (see FIG. 18), the line showing first connection side surface 32r is longer than the line showing second connection side surface 32s. When seen in a plan view of main surface 11m of wafer 11 (see FIG. 18), first guide groove 32c has a trapezoidal shape having second connection side surface 32s as an upper base and first connection side surface 32r as a lower base. In the present embodiment, angle α₃₂ of first guide groove 32c and angle 1332 of first guide groove 32c each are defined at 45 degrees or more and less than 90 degrees. Accordingly, the side surfaces (for example, first side surface 32p, second side surface 33p, third side surface 32q, and fourth side surface 33q) of each of the guide grooves (first guide groove 32c, second guide groove 33c, guide grooves 31c, 34c, and 35c) along division reference line 14 may have an angle of about 45 degrees or less with respect to division reference line 14.

Also in the present embodiment, the distance between second side surface 33p and division reference line 14 is shorter than the distance between first side surface 32p and division reference line 14, like the fifth embodiment. In the present embodiment, first side surface 32p and second side surface 33p are inclined with respect to division reference line 14. Thus, in the case where the distance between second side surface 33p and division reference line 14 is compared with the distance between first side surface 32p and division reference line 14, the distance between division reference line 14 and the end of first side surface 32p in the cleavage direction (on the end point F side) is compared with the distance between division reference line 14 and the end of second side surface 33p in the direction opposite to the cleavage direction (on the start point S side).

When seen in a plan view of main surface 11m of wafer 11 (see FIG. 18), groove width W1 is defined as a length of the line showing the connection side surface, which is closer to start point S, of a pair of connection side surfaces connecting a pair of side surfaces along division reference line 14. When seen in a plan view of main surface 11m of wafer 11 (see FIG. 18), for example, groove width W1 of first guide groove 32c corresponds to a length of the line showing first connection side surface 32r. Groove step distance S1 is defined as a difference between (i) the distance between division reference line 14 and the end of first side surface 32p in the cleavage direction (on the end point F side) and (ii) the distance between division reference line 14 and the end of second side surface 33p in the direction opposite to the cleavage direction (on the start point S side).

Within one region of two regions sandwiching division reference line 14, the side surfaces (for example, first side surface 32p and second side surface 33p) of each of the guide grooves (first guide groove 32c, second guide groove 33c, guide grooves 31c, 34c, and 35c) along division reference line 14 are arranged at the same inclination with respect to division reference line 14. Within the other region of two regions sandwiching division reference line 14, the side surfaces (for example, third side surface 32q and fourth side surface 33q) of each of the guide grooves (first guide groove 32c, second guide groove 33c, guide grooves 31c, 34c, and 35c) along division reference line 14 are also arranged at the same inclination with respect to division reference line 14.

In the present embodiment, division line 16 deviated from division reference line 14 in the direction of first side surface 32p and second side surface 33p is not only corrected toward division reference line 14 at the ends of the plurality of guide grooves (first guide groove 32c, second guide groove 33c, guide grooves 31c, 34c, and 35c) on the end point F side as in the fifth embodiment, but also corrected toward division reference line 14 along first side surface 32p and second side surface 33p. Division line 16 deviated from division reference line 14 in the direction of third side surface 32q and fourth side surface 33q is not only corrected toward division reference line 14 at the end of each of the plurality of guide grooves (first guide groove 32c, second guide groove 33c, guide grooves 31c, 34c, and 35c) on the end point F side as in the fifth embodiment, but also corrected toward division reference line 14 along third side surface 32q and fourth side surface 33q.

The effect of the method of manufacturing a semiconductor device 12 of the present embodiment will be hereinafter described. The effect of the method of manufacturing a semiconductor device 12 of the present embodiment mainly has the following effects in addition to the effects similar to those achieved by the method of manufacturing a semiconductor device 12 of the fifth embodiment.

Guide groove group 30c of the present embodiment serves to correct division line 16 toward division reference line 14 at the ends of the plurality of guide grooves (first guide groove 32c, second guide groove 33c, guide grooves 31c, 34c, and 35c) on the end point F side, and at first side surface 32p, second side surface 33p, third side surface 32q, and fourth side surface 33q. According to the method of manufacturing a semiconductor device 12 of the present embodiment, cleavage of wafer 11 largely deviated from division reference line 14 can be suppressed.

Furthermore, in the method of manufacturing a semiconductor device 12 of the present embodiment, a pair of side surfaces of each guide groove (first guide groove 32c, second guide groove 33c, guide grooves 31c, 34c, and 35c) along the direction of division reference line 14 are located to sandwich division reference line 14. Accordingly, even if division line 16 is deviated from cleavage start point groove 18d toward either of a pair of side surfaces (first side surface 32p and third side surface 32q) of first guide groove 32c along division reference line 14, division line 16 may be corrected toward division reference line 14. In other words, when division line 16 is deviated from division reference line 14 toward one region of two regions sandwiching division reference line 14, division line 16 is corrected by first side surface 32p and second side surface 33p. When division line 16 is deviated from division reference line 14 to the other region of two regions sandwiching division reference line 14, division line 16 is corrected by third side surface 32q and fourth side surface 33q.

### Ninth Embodiment

Referring to FIG. 27, a method of manufacturing a semiconductor device 12 according to the eighth embodiment will be hereinafter described. The method of manufacturing a semiconductor device 12 according to the present embodiment includes basically the same steps as those of the method of manufacturing a semiconductor device 12 of the eighth embodiment, but is different therefrom mainly in the following points. The present embodiment is different from the eighth embodiment in the position of guide groove group 30d relative to division reference line 14.

In the method of manufacturing a semiconductor device 12 of the present embodiment, when seen in a plan view of main surface 11m of wafer 11 (see FIG. 18), a plurality of guide grooves (first guide groove 32d, second guide groove 33d, a plurality of guide grooves 31d, 34d, and 35d) included in guide groove group 30d each have a trapezoidal shape. One side surface of a pair of side surfaces of each of the plurality of guide grooves (first guide groove 32d, second guide groove 33d, guide grooves 31d, 34d, and 35d) along division reference line 14 is located on division reference line 14. For example, third side surface 32q of first guide groove 32 and fourth side surface 33q of second guide groove 33 are located on division reference line 14.

Within one region of two regions sandwiching division reference line 14, the side surfaces (for example, first side surface 32p and second side surface 33p) of each of the plurality of guide grooves (first guide groove 32d, second guide groove 33d, guide grooves 31d, 34d, and 35d) along division reference line 14 are arranged at the same inclination with respect to division reference line 14. In the present embodiment, division line 16 deviated from division reference line 14 in the direction of first side surface 32p and second side surface 33p is not only corrected toward division reference line 14 at the ends of the plurality of guide grooves (first guide groove 32d, second guide groove 33d, guide grooves 31d, 34d, and 35d) on the end point F side as in the fifth embodiment, but also corrected toward division reference line 14 along first side surface 32p and second side surface 33p.

The effect of the method of manufacturing a semiconductor device 12 of the present embodiment will be hereinafter described. The effect of the method of manufacturing a semiconductor device 12 of the present embodiment mainly has the following effects in addition to the effects similar to those achieved by the method of manufacturing a semiconductor device 12 of the eighth embodiment.

When division line 16 is deviated from start point S in the direction of first side surface 32p of first guide groove 32, guide groove group 30d of the present embodiment corrects division line 16 toward division reference line 14 at the ends of the plurality of guide grooves (first guide groove 32d, second guide groove 33d, guide grooves 31d, 34d, and 35d) on the end point F side, and also at first side surface 32p and second side surface 33p. According to the method of manufacturing a semiconductor device 12 of the present embodiment, cleavage of wafer 11 largely deviated from division reference line 14 can be suppressed. Furthermore, when division line 16 is corrected toward division reference line 14 by the plurality of guide grooves (first guide groove 32d, second guide groove 33d, guide grooves 31d, 34d, and 35d) and brought into contact with the side surfaces (for example, third side surface 32q and fourth side surface 33q) of each of the plurality of guide grooves (first guide groove 32d, second guide groove 33d, guide grooves 31d, 34d, and 35d) along division reference line 14, division line 16 extends along the side surfaces (for example, third side surface 32q and fourth side surface 33q) of the plurality of guide grooves (first guide groove 32d, second guide groove 33d, guide grooves 31d, 34d, and 35d) on division reference line 14.

### Tenth Embodiment

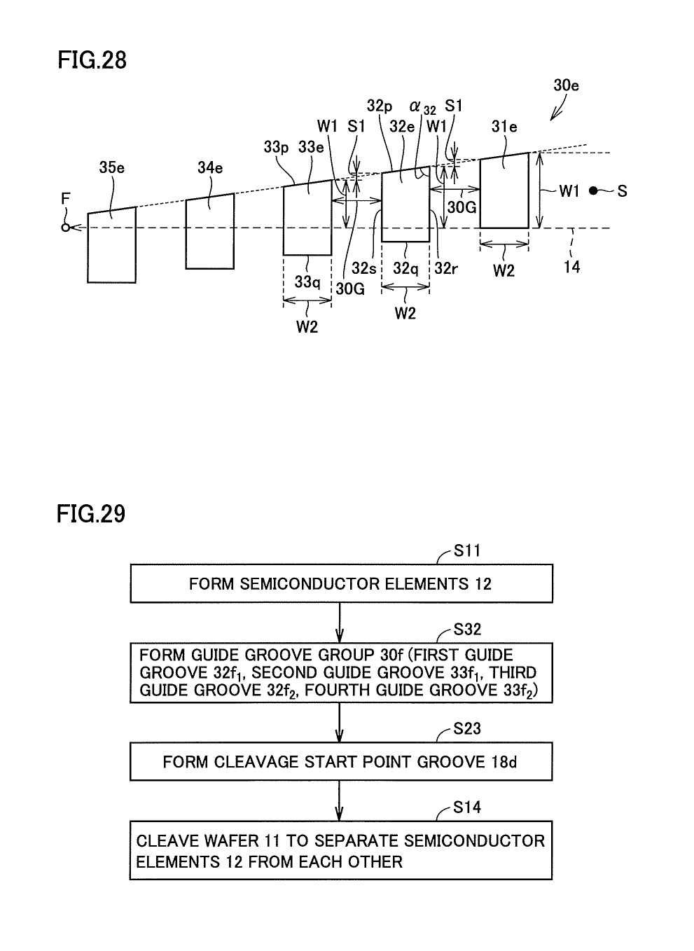

Referring to FIG. 28, a method of manufacturing a semiconductor device 12 according to the tenth embodiment will be hereinafter described. The method of manufacturing a semiconductor device 12 of the present embodiment includes basically the same steps as those of the method of manufacturing a semiconductor device 12 of the seventh embodiment, but is different therefrom mainly in the following points.

The present embodiment is different from the seventh embodiment in shapes of a plurality of guide grooves (first guide groove 32e, second guide groove 33e, guide grooves 31e, 34e, and 35e) included in a guide groove group 30e. Specifically, each of the plurality of guide grooves (first guide groove 32b, second guide groove 33b, guide grooves 31b, 34b, and 35b) of the seventh embodiment has a rectangular shape when seen in a plan view of main surface 11m of wafer 11 (see FIG. 18). On the other hand, each of the plurality of guide grooves (first guide groove 32e, second guide groove 33e, guide grooves 31e, 34e, and 35e) of the present embodiment has a trapezoidal shape when seen in a plan view of main surface 11m of wafer 11 (see FIG. 18).

With reference to first guide groove 32e as an example, the shapes of the plurality of guide grooves (first guide groove 32e, second guide groove 33e, guide grooves 31e, 34e, and 35e) of the present embodiment will be hereinafter described. First side surface 32p and third side surface 32q extend along division reference line 14. In the present embodiment, the side surfaces along division reference line 14 do not need to be strictly parallel to division reference line 14 like the fifth embodiment. The side surfaces along division reference line 14 do not need to be located on division reference line 14. Among the side surfaces connecting first side surface 32p and third side surface 32q, the side surface close to start point S corresponds to a first connection side surface 32r, and the side surface close to end point F corresponds to a second connection side surface 32s. An angle α₃₂ of first guide groove 32e formed between first side surface 32p and first connection side surface 32r is defined at 45 degrees or more and less than 90 degrees, and preferably 80 degrees or more and less than 90 degrees.

When seen in a plan view of main surface 11m of wafer 11 (see FIG. 18), the line showing first connection side surface 32r is longer than the line showing second connection side surface 32s. When seen in a plan view of main surface 11m of wafer 11 (see FIG. 18), first guide groove 32e has a trapezoidal shape having second connection side surface 32s as an upper base and first connection side surface 32r as a lower base. In the present embodiment, angle α₃₂ of first guide groove 32e is defined at 45 degrees or more and less than 90 degrees. Thus, the side surfaces (for example, first side surface 32p and second side surface 33p) of the plurality of guide grooves (first guide groove 32e, second guide groove 33e, guide grooves 31e, 34e, and 35e) along division reference line 14 each may form an angle of about 45 degrees or less with respect to division reference line 14.

Within one region of two regions sandwiching division reference line 14, the side surfaces (for example, first side surface 32p and second side surface 33p) of each of the guide grooves (first guide groove 32e, second guide groove 33e, guide grooves 31e, 34e, and 35e) along division reference line 14 are arranged at the same inclination with respect to division reference line 14. Within the other region of two regions sandwiching division reference line 14, the side surfaces (for example, third side surface 32q and fourth side surface 33q) of each of the guide grooves (first guide groove 32e, second guide groove 33e, guide grooves 31e, 34e, and 35e) along division reference line 14 are also arranged at the same inclination with respect to division reference line 14. In the present embodiment, division line 16 deviated from division reference line 14 in the direction of first side surface 32p and second side surface 33p is not only corrected toward division reference line 14 at the ends of the plurality of guide grooves (first guide groove 32e, second guide groove 33e, guide grooves 31e 34e, and 35e) on the end point F side as in the fifth embodiment, but also corrected toward division reference line 14 along first side surface 32p and second side surface 33p.

The effect of the method of manufacturing a semiconductor device 12 of the present embodiment will be hereinafter described. The effect of the method of manufacturing a semiconductor device 12 of the present embodiment mainly has the following effects in addition to the effects similar to those achieved by the method of manufacturing a semiconductor device 12 of the seventh embodiment.

When division line 16 is deviated from start point S in the direction of first side surface 32p of first guide groove 32e, guide groove group 30e of the present embodiment corrects division line 16 toward division reference line 14 at the ends of the plurality of guide grooves (first guide groove 32e, second guide groove 33e, guide grooves 31e, 34e, and 35e) on the end point F side, and also at first side surface 32p and second side surface 33p, in the same manner as with guide groove group 30b of the seventh embodiment. According to the method of manufacturing a semiconductor device 12 of the present embodiment, cleavage of wafer 11 largely deviated from division reference line 14 can be suppressed. Furthermore, when division line 16 is corrected toward division reference line 14 by the plurality of guide grooves (first guide groove 32e, second guide groove 33e, guide grooves 31e, 34e, and 35e) and brought into contact with division reference line 14, division line 16 extends along division reference line 14.

In the method of manufacturing a semiconductor device 12 according to the present embodiment, the guide grooves (first guide groove 32e, second guide groove 33e, guide grooves 31e, 34e, and 35e) have the same bottom surface area, as in the seventh embodiment. Accordingly, the mask openings having the same area are applied when wafer 11 is etched to form a plurality of guide grooves (first guide groove 32e, second guide groove 33e, guide grooves 31e, 34e, and 35e). In the method of manufacturing a semiconductor device 12 according to the present embodiment, when a plurality of guide grooves (first guide groove 32e, second guide groove 33e, guide grooves 31e, 34e, and 35e) included in guide groove group 30e are simultaneously formed, these guide grooves (first guide groove 32e, second guide groove 33e, guide grooves 31e, 34e, and 35e) may be suppressed from having different depths. According to the method of manufacturing a semiconductor device 12 of the present embodiment, the accuracy in correcting division line 16 toward division reference line 14 is further improved, so that cleavage of wafer 11 largely deviated from division reference line 14 may be further suppressed.

### Eleventh Embodiment

Referring to FIGS. 29 to 31, a method of manufacturing a semiconductor device 12 according to the eleventh embodiment will be hereinafter described. The method of manufacturing a semiconductor device 12 according to the present embodiment includes basically the same steps as those of the method of manufacturing a semiconductor device 12 of the fifth embodiment, but is different therefrom mainly in the following points.

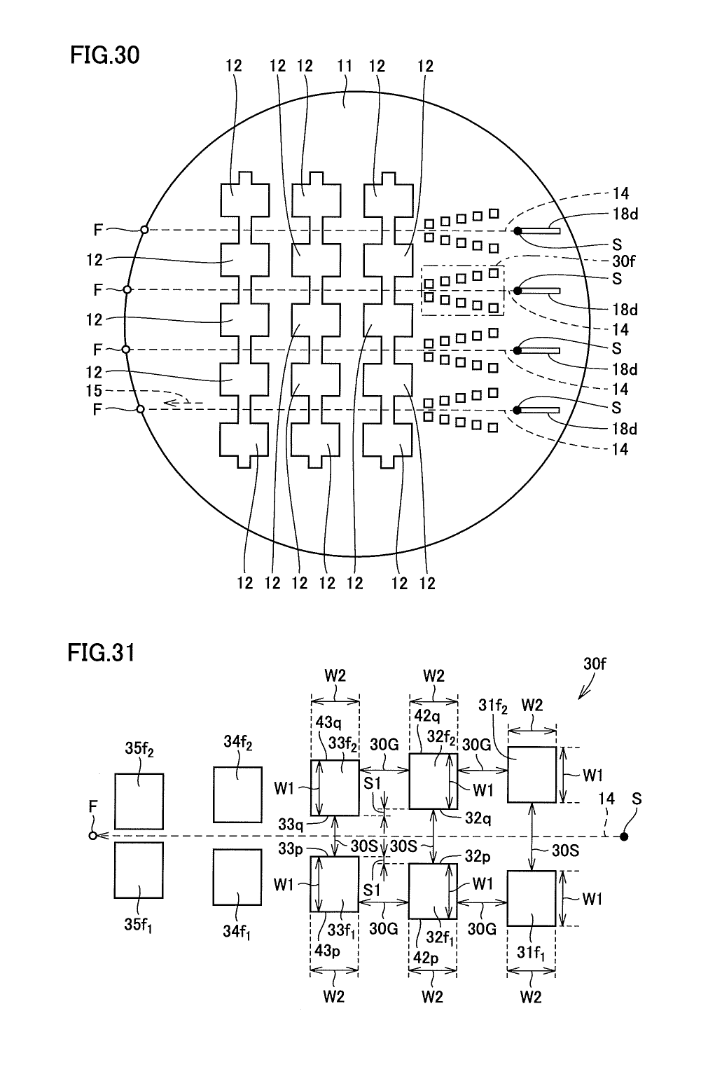

Referring to FIGS. 29 and 30, the method of manufacturing a semiconductor device 12 of the present embodiment includes forming a plurality of guide groove groups 30f on wafer 11 (S32). Each of the plurality of guide groove groups 30f includes a first guide groove 32f₁, a second guide groove 33f₁, a third guide groove 32f₂, a fourth guide groove 33f₂, and guide grooves 31f₁, 31f₂, 34f₁, 34f₂, 35f₁, 35f₂. One guide groove group 30f may be formed for one division reference line 14.

First guide groove 32f₁ has a first side surface 32p located in one region of two regions. Second guide groove 33f₁ is located at a distance from first guide groove 32f₁ toward end point F. Second guide groove 33f₁ has a second side surface 33p located in one region of two regions. Third guide groove 32f₂ has a third side surface 32q located in the other region of two regions. Fourth guide groove 33f₂ is located at a distance from third guide groove 32f₂ toward end point F. Fourth guide groove 33f₂ has a fourth side surface 33q located in the other region of two regions.

In the method of manufacturing a semiconductor device 12 of the present embodiment, a start point S is located on division reference line 14. Start point S is preferably located between the guide grooves (for example, first guide groove 32f₁ and second guide groove 33f₁) located in one region and the guide grooves (for example, third guide groove 32f₂ and fourth guide groove 33f₂) located in the other region in the state where division reference line 14 is interposed between one region and the other region. End point F is located on division reference line 14. Second guide groove 33f₁ is provided close to end point F relative to first guide groove 32f₁. Fourth guide groove 33f₂ is provided close to end point F relative to third guide groove 32f₂. Each of first side surface 32p, second side surface 33p, third side surface 32q, and fourth side surface 33q corresponds to a side surface located closer to division reference line 14 among the side surfaces of each of the plurality of guide grooves (for example, first guide groove 32f₁, second guide groove 33f₁, third guide groove 32f₂, and fourth guide groove 33f₂) along division reference line 14.

Referring to FIG. 31, a fifth side surface 42p of first guide groove 32f₁ that faces first side surface 32p is located in one region of two regions sandwiching division reference line 14. The distance between fifth side surface 42p and division reference line 14 is longer than the distance between first side surface 32p and division reference line 14. A sixth side surface 43p of second guide groove 33f₁ that faces second side surface 33p is located in one region of two regions sandwiching division reference line 14. The distance between sixth side surface 43p and division reference line 14 is longer than the distance between second side surface 33p and division reference line 14.

A seventh side surface 42q of third guide groove 32f₂ that faces third side surface 32q is located in the other region of two regions sandwiching division reference line 14. The distance between seventh side surface 42q and division reference line 14 is longer than the distance between third side surface 32q and division reference line 14. An eighth side surface 43q of fourth guide groove 33f₂ that faces fourth side surface 33q is located in the other region of two regions sandwiching division reference line 14. The distance between eighth side surface 43q and division reference line 14 is longer than the distance between fourth side surface 33q and division reference line 14.

The distance between second side surface 33p and division reference line 14 is shorter than the distance between first side surface 32p and division reference line 14. The distance between fourth side surface 33q and division reference line 14 is shorter than the distance between third side surface 32q and division reference line 14. The guide grooves (first guide groove 32f₁, second guide groove 33f₁, third guide groove 32f₂, fourth guide groove 33f₂, and guide grooves 31f₁, 31f₂, 34f₁, 34f₂, 35f₁, 35f₂) have the same bottom surface area.

Within one region of two regions sandwiching division reference line 14, first guide groove 32f₁ and second guide groove 33f₁ adjacent to each other may be repeatedly arranged. In other words, the relative positional relation between guide groove 31f₁ and first guide groove 32f₁; the relative positional relation between second guide groove 33f₁ and guide groove 34f₁; and the relative positional relation between guide groove 34f₁ and guide groove 35f₁ each are the same as the relative positional relation between first guide groove 32f₁ and second guide groove 33f₁. Within the other region of two regions sandwiching division reference line 14, third guide groove 32f₂ and fourth guide groove 33f₂ adjacent to each other may be repeatedly arranged. In other words, the relative positional relation between guide groove 31f₂ and third guide groove 32f₂; the relative positional relation between fourth guide groove 33f₂ and guide groove 34f₂; and the relative positional relation between guide groove 34f₂ and guide groove 35f₂ each are the same as the relative positional relation between third guide groove 32f₂ and fourth guide groove 33f₂.

Guide groove group 30f of the present embodiment corrects division line 16, which is deviated from division reference line 14, toward division reference line 14. Division line 16 deviated from division reference line 14 toward one region of two regions sandwiching division reference line 14 is corrected toward division reference line 14 by first side surface 32p and second side surface 33p. Division line 16 deviated from division reference line 14 toward the other region of two regions sandwiching division reference line 14 is corrected toward division reference line 14 by third side surface 32q and fourth side surface 33q.

Guide groove group 30 of the fifth embodiment corrects division line 16 toward division reference line 14 in the following manner. Division line 16 contacts one guide groove. When the extension line of division line 16 in this one guide groove is located inside another guide groove adjacent thereto in the cleavage direction (the direction from start point S toward end point F), division line 16 is not corrected by this one guide groove. When the extension line of division line 16 in this one guide groove is located outside another guide groove adjacent thereto in the cleavage direction (the direction from start point S toward end point F), division line 16 is corrected by this one guide groove. Specifically, division line 16 is corrected toward division reference line 14 at the end of this one guide groove in the cleavage direction (on the end point F side).

In contrast, guide groove group 30f of the present embodiment corrects division line 16 toward division reference line 14 in the following manner. Division line 16 contacts one guide groove. When the extension line of division line 16 in this one guide groove is located inside another guide groove adjacent thereto in the cleavage direction (the direction from start point S toward end point F), division line 16 is corrected by this one guide groove. Specifically, division line 16 is corrected toward division reference line 14 at the end of this one guide groove in the direction opposite to the cleavage direction (on the start point S side). When the extension line of division line 16 in this one guide groove is located outside another guide groove adjacent thereto in the cleavage direction (the direction from start point S toward end point F), division line 16 is not corrected by this one guide groove.

The effect of the method of manufacturing a semiconductor device 12 of the present embodiment will be hereinafter described. The method of manufacturing a semiconductor device 12 according to the present embodiment achieves basically the same effects as those of the method of manufacturing a semiconductor device 12 of the fifth embodiment, but is different therefrom mainly in the following points.

When division line 16 is deviated from start point S in the direction of first side surface 32p of first guide groove 32, guide groove group 30f of the present embodiment corrects division line 16 toward division reference line 14. According to the method of manufacturing a semiconductor device 12 of the present embodiment, cleavage of wafer 11 largely deviated from division reference line 14 can be suppressed. Furthermore, according to the method of manufacturing a semiconductor device 12 of the present embodiment, even if division line 16 is deviated from cleavage start point groove 18d toward either of a pair of side surfaces (for example, first side surface 32p and third side surface 32q) of each of the plurality of guide grooves (first guide groove 32f₁, second guide groove 33f₁, third guide groove 32f₂, fourth guide groove 33f₂, and guide grooves 31f₁, 31f₂, 34f₁, 34f₂, 35f₁, 35f₂) along division reference line 14, division line 16 may be corrected toward division reference line 14.

In the method of manufacturing a semiconductor device 12 of the present embodiment, the guide grooves (first guide groove 32f₁, second guide groove 33f₁, third guide groove 32f₂, fourth guide groove 33f₂, and guide grooves 31f₁, 31f₂, 34f₁, 34f₂, 35f₁, 35f₂) have the same bottom surface area. Accordingly, the mask openings having the same area are applied when wafer 11 is etched to form a plurality of guide grooves (first guide groove 32f₁, second guide groove 33f₁, third guide groove 32f₂, fourth guide groove 33f₂, and guide grooves 31f₁, 31f₂, 34f₁, 34f₂, 35f₁, 35f₂). In the method of manufacturing a semiconductor device 12 according to the present embodiment, when the plurality of guide grooves (first guide groove 32f₁, second guide groove 33f₁, third guide groove 32f₂, fourth guide groove 33f₂, and guide grooves 31f₁, 31f₂, 34f₁, 34f₂, 35f₁, 35f₂) included in guide groove group 30f are simultaneously formed, guide grooves (first guide groove 32f₁, second guide groove 33f₁, third guide groove 32f₂, fourth guide groove 33f₂, and guide grooves 31f₁, 31f₂, 34f₁, 34f₂, 35f₁, 35f₂) may be suppressed from having different depths. According to the method of manufacturing a semiconductor device 12 of the present embodiment, the accuracy in correcting division line 16 toward division reference line 14 is further improved, so that cleavage of wafer 11 largely deviated from division reference line 14 may be further suppressed.

### Twelfth Embodiment

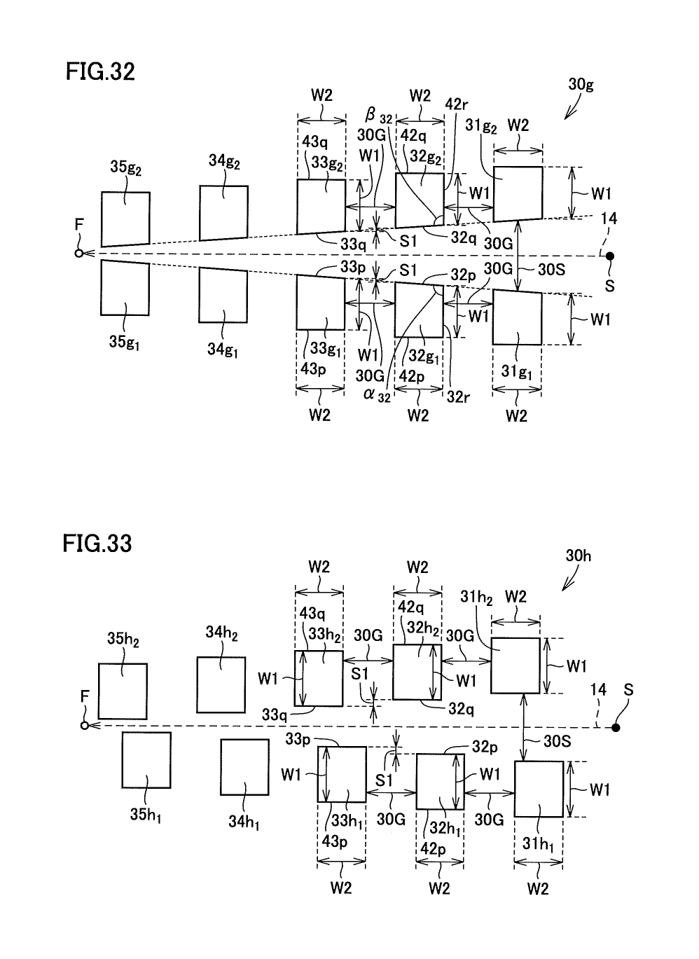

Referring to FIG. 32, a method of manufacturing a semiconductor device 12 according to the twelfth embodiment will be hereinafter described. The method of manufacturing a semiconductor device 12 according to the present embodiment includes basically the same steps as those of the method of manufacturing a semiconductor device 12 of the eleventh embodiment, but is different therefrom mainly in the following points.

The present embodiment is different from the eleventh embodiment in shapes of a plurality of guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) included in guide groove group 30g. Each of the plurality of guide grooves (first guide groove 32f₁, second guide groove 33f₁, third guide groove 32f₂, fourth guide groove 33f₂, guide grooves 31f₁, 31f₂, 34f₁, 34f₂, 35f₁, 35f₂) of the eleventh embodiment has a rectangular shape when seen in a plan view of main surface 11m of wafer 11 (see FIG. 18). On the other hand, each of the plurality of guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) of the present embodiment has a trapezoidal shape when seen in a plan view of main surface 11m of wafer 11 (see FIG. 18).

With reference to first guide groove 32g₁ as an example, the shapes of the plurality of guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) of the present embodiment will be hereinafter described. First side surface 32p and fifth side surface 42p each extend along division reference line 14. In the present embodiment, the side surface along division reference line 14 does not need to be strictly parallel to division reference line 14. The side surface along division reference line 14 does not need to be located on division reference line 14. Among the side surfaces connecting first side surface 32p and fifth side surface 42p, the side surface closer to start point S corresponds to first connection side surface 32r. An angle α₃₂ of first guide groove 32g₁ formed between first side surface 32p and first connection side surface 32r is defined at 90 degrees or more and 135 degrees or less, and preferably 90 degrees or more and 100 degrees or less. Third side surface 32q and seventh side surface 42q extend along division reference line 14. Among the side surfaces connecting third side surface 32q and seventh side surface 42q, the side surface closer to start point S corresponds to third connection side surface 42r. An angle β₃₂ of third guide groove 32g₂ formed between third side surface 32q and third connection side surface 42r is defined at 90 degrees or more and 135 degrees or less, and preferably 90 degrees or more and 100 degrees or less.

Within one region of two regions sandwiching division reference line 14, the side surfaces (for example, first side surface 32p, second side surface 33p), which are closer to division reference line 14, among pairs of side surfaces of each guide groove (for example, first guide groove 32g₁, second guide groove 33g₁, guide grooves 31g₁, 34g₁, 35g₁) along division reference line 14 are arranged at the same inclination with respect to division reference line 14. Within the other region of two regions sandwiching division reference line 14, the side surfaces (for example, third side surface 32q, fourth side surface 33q), which are closer to division reference line 14, among pairs of side surfaces of each guide groove (for example, third guide groove 32g₂, fourth guide groove 33g₂, guide grooves 31g₂, 34g₂, 35g₂) along division reference line 14 are also arranged at the same inclination with respect to division reference line 14. The guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) have the same bottom surface area.

In the method of manufacturing a semiconductor device 12 of the present embodiment, division line 16 deviated from division reference line 14 is not only corrected toward division reference line 14 at the ends of the plurality of guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) on the start point S side as in the eleventh embodiment, but also corrected along first side surface 32p and second side surface 33p or along third side surface 32q and fourth side surface 33q.

The effect of the method of manufacturing a semiconductor device 12 of the present embodiment will be hereinafter described. The effect of the method of manufacturing a semiconductor device 12 of the present embodiment mainly has the following effects in addition to the effects similar to those achieved by the method of manufacturing a semiconductor device 12 of the eleventh embodiment.

Guide groove group 30g of the present embodiment corrects division line 16 toward division reference line 14 at the ends of the plurality of guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) on the start point S side, and also at first side surface 32p, second side surface 33p, third side surface 32q, and fourth side surface 33q. According to the method of manufacturing a semiconductor device 12 of the present embodiment, cleavage of wafer 11 largely deviated from division reference line 14 can be suppressed.

Furthermore, in the method of manufacturing a semiconductor device 12 of the present embodiment, a pair of side surfaces (for example, first side surface 32p and third side surface 32q) of each guide groove (first guide groove 32g₁, second guide groove 33g₁, third guide groove 32g₂, fourth guide groove 33g₂, guide grooves 31g₁, 31g₂, 34g₁, 34g₂, 35g₁, 35g₂) along division reference line 14 sandwich division reference line 14. Accordingly, even if division line 16 is deviated from cleavage start point groove 18d toward either of the pair of side surfaces (for example, first side surface 32p and third side surface 32q) along division reference line 14, division line 16 may be corrected toward division reference line 14.

In the method of manufacturing a semiconductor device 12 of the present embodiment, the guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) have the same bottom surface area. The mask openings having the same area are applied when wafer 11 is etched to form a plurality of guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂). Accordingly, in the method of manufacturing a semiconductor device 12 of the present embodiment, when a plurality of guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) included in guide groove group 30g are simultaneously formed, the guide grooves (first guide groove 32g₁, second guide groove 33g₁, third guide groove 32g₂, fourth guide groove 33g₂, guide grooves 31g₁, 31g₂, 34g₁, 34g₂, 35g₁, 35g₂) may be suppressed from having different depths. According to the method of manufacturing a semiconductor device 12 of the present embodiment, the accuracy in correcting division line 16 toward division reference line 14 is further improved, so that cleavage of wafer 11 largely deviated from division reference line 14 may be further suppressed.

### Thirteenth Embodiment

Referring to FIG. 33, a method of manufacturing a semiconductor device 12 according to the thirteenth embodiment will be hereinafter described. The method of manufacturing a semiconductor device 12 according to the present embodiment basically includes the same steps and achieves the same effects as those of the method of manufacturing a semiconductor device 12 of the eleventh embodiment, but is different therefrom mainly in the following points.

The present embodiment is different from the eleventh embodiment in the arrangement of a plurality of guide grooves (a first guide groove 32h₁, a second guide groove 33h₁, a third guide groove 32h₂, a fourth guide groove 33h₂, guide grooves 31h₁, 31h₂, 34h₁, 34h₂, 35h₁, 35h₂). In the eleventh embodiment, first guide groove 32f₁ and third guide groove 32f₂ are arranged so as to be mirror symmetrical with respect to division reference line 14, and second guide groove 33f₁ and fourth guide groove 33f₂ are arranged so as to be mirror symmetrical with respect to division reference line 14.

On the other hand, in the present embodiment, first guide groove 32h₁ and third guide groove 32h₂ do not need to be arranged so as to be mirror symmetrical with respect to division reference line 14, and also second guide groove 33h₁ and fourth guide groove 33h₂ do not need to be arranged so as to be mirror symmetrical with respect to division reference line 14. In the direction along division reference line 14, third guide groove 32h₂, fourth guide groove 33h₂, and guide grooves 31h₂, 34h₂, 35h₂ may be arranged so as to be deviated from first guide groove 32h₁, second guide groove 33h₁, and guide groove 31h₁, 34h₁, 35h₁, respectively, toward end point F (in the direction opposite to cleavage start point groove 18d).

### Fourteenth Embodiment

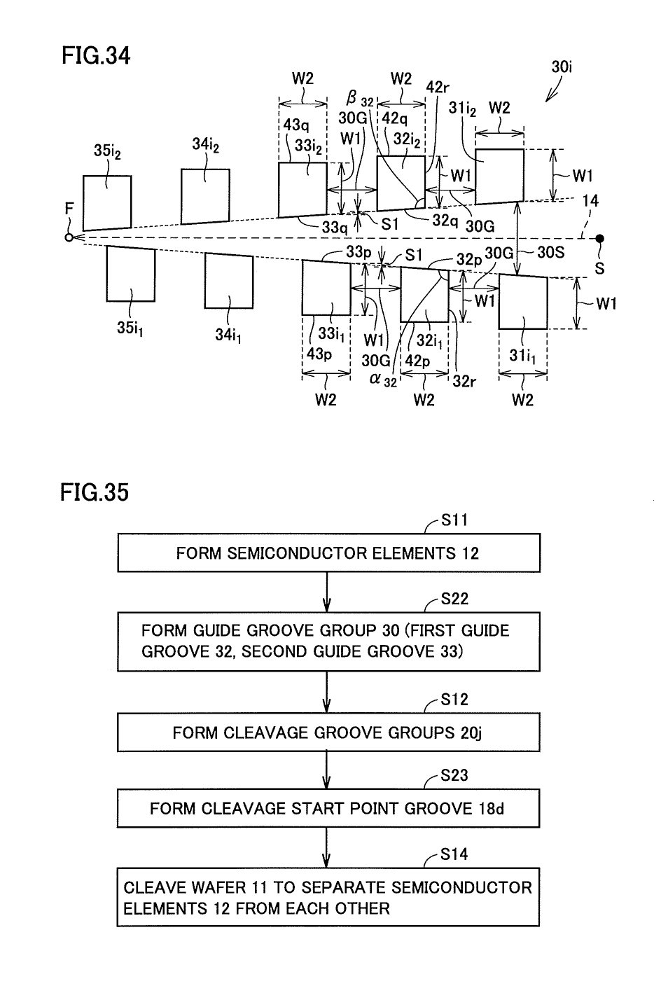

Referring to FIG. 34, a method of manufacturing a semiconductor device 12 according to the fourteenth embodiment will be hereinafter described. The method of manufacturing a semiconductor device 12 of the present embodiment basically includes the same steps and achieves the same effects as those of the method of manufacturing a semiconductor device 12 of the twelfth embodiment, but is different therefrom mainly in the following points.

The present embodiment is different from the twelfth embodiment in the arrangement of a plurality of guide grooves (a first guide groove 32i₁, a second guide groove 33i₁, a third guide groove 32i₂, a fourth guide groove 33i₂, guide grooves 31i₁, 31i₂, 34i₁, 34i₂, 35i₁, 35i₂) included in a guide groove group 30i. In the twelfth embodiment, first guide groove 32g₁ and third guide groove 32g₂ are arranged so as to be mirror symmetrical with respect to division reference line 14, and also, second guide groove 33g₁ and fourth guide groove 33g₂ are arranged so as to be mirror symmetrical with respect to division reference line 14.

On the other hand, in the present embodiment, first guide groove 32i₁ and third guide groove 32i₂ do not need to be arranged so as to be mirror symmetrical with respect to division reference line 14, and also, second guide groove 33i₁ and fourth guide groove 33i₂ do not need to be arranged so as to be mirror symmetrical with respect to division reference line 14. In the direction along division reference line 14, third guide groove 32i₂, fourth guide groove 33i₂, and guide grooves 31i₂, 34i₂, and 35i₂ may be arranged so as to be deviated from first guide groove 32i₁, second guide groove 33i₁, guide grooves 31i₁, 34i₁, 35i₁, respectively, toward end point F (in the direction opposite to cleavage start point groove 18d).

### Fifteenth Embodiment

Referring to FIGS. 35 to 37, a method of manufacturing a semiconductor device 12 according to the fifteenth embodiment will be hereinafter described. The method of manufacturing a semiconductor device 12 according to the present embodiment basically includes the same steps and achieves the same effects as those of the method of manufacturing a semiconductor device 12 of the fifth embodiment, but is different therefrom mainly in the following points.

The method of manufacturing a semiconductor device 12 of the present embodiment further includes forming a plurality of cleavage groove groups 20j (S22). Each of the plurality of cleavage groove groups 20j includes a cleavage groove 21 and a cleavage groove 22. The plurality of cleavage groove groups 20j are located on division reference line 14. The plurality of cleavage groove groups 20j are arranged between a plurality of semiconductor devices 12 adjacent to each other. Wafer 11 includes a plurality of cleavage grooves 21 and 22.

In the method of manufacturing a semiconductor device 12 of the present embodiment, in the step (S11) of forming a plurality of semiconductor devices 12 on wafer 11, a plurality of semiconductor devices 12 may be formed in the state where semiconductor devices 12 are deviated in the azimuth angle direction in main surface 11m of wafer 11 (see FIG. 18) with respect to division reference line 14. In this case, cleavage line 15 is deviated in the azimuth angle direction in main surface 11m of wafer 11 (see FIG. 18) with respect to division reference line 14. Even if division line 16 deviated from start point S on division reference line 14 is corrected toward division reference line 14 by guide groove group 30, division line 16 is caused to extend from guide groove group 30 along cleavage line 15 inclined by an azimuth angle θ with respect to division reference line 14.

In the method of manufacturing a semiconductor device 12 of the present embodiment, a plurality of cleavage groove groups 20j are formed in addition to guide groove group 30. Stress is generated at an edge portion of each of the plurality of cleavage grooves 21 and 22 included in each of the plurality of cleavage groove groups 20j, that is, at a portion of wafer 11 that faces each of the plurality of cleavage grooves 21 and 22. At the first end on the start point S side and the second end on the end point F side in each of the plurality of guide grooves (first guide groove 32, second guide groove 33, guide grooves 31, 34 and 35), stress is generated not only in the cleavage direction but also in the direction perpendicular to the cleavage direction (that is, in the width direction of the guide groove). Due to this stress, division line 16 is corrected toward division reference line 14 at the second end of each of the plurality of guide grooves (for example, first guide groove 32, second guide groove 33, guide grooves 34 and 35) in the cleavage direction.

In the method of manufacturing a semiconductor device 12 of the present embodiment, a plurality of cleavage grooves 21 and 22 are formed between the plurality of semiconductor devices 12. By forming a plurality of cleavage grooves 21 and 22 between the plurality of semiconductor devices 12, division line 16 extending along cleavage line 15 inclined with respect to division reference line 14 is brought into contact with the plurality of cleavage grooves 21 and 22. The plurality of cleavage grooves 21 and 22 can correct division line 16 toward division reference line 14 before division line 16 is largely deviated from division reference line 14. According to the method of manufacturing a semiconductor device 12 of the present embodiment, division line 16 inclined by an azimuth angle θ with respect to division reference line 14 may be corrected so as to be brought closer to division reference line 14 more accurately.

It should be understood that the embodiments disclosed herein are illustrative and non-restrictive in every respect. At least two of the first embodiment to the fifteenth embodiment disclosed herein may be combined together as long as there is no inconsistency. The scope of the present invention is defined by the terms of the claims, rather than the description above, and is intended to include any modifications within the meaning and scope equivalent to the terms of the claims. Each of the embodiments may be modified or omitted as appropriate within the scope of the present invention. Dimensions, materials and shapes of each component, relative configurations thereof, and the like exemplified in each of the embodiments may be modified as appropriate in accordance with the device configurations and various conditions to which the present invention is applicable. The dimensions of each component in each figure may be different from actual dimensions.

### REFERENCE SIGNS LIST

11 wafer, 11m main surface, 11s cleavage plane, 12 semiconductor device, 13 active region, 14 division reference line, 15 cleavage line, 16 division line, 16s device separation line, 17 division line (in the case of no grooves), 18 cleavage start point, 18d cleavage start point groove, 19 blade, 20, 20b, 20c, 20j cleavage groove group, 20G, distance, 20a1 first cleavage groove group, 20a2 second cleavage groove group, 21, 21c, 22, 22c, 23, 23c cleavage groove, 21L, 22L, 23L, W2 groove length, 21W, 22W, 23W, W1 groove width, 25, C1, C2, C3 level difference, 30, 30a, 30b, 30c, 30d, 30e, 30f, 30g, 30i guide groove group, 30G groove distance, 31, 31a, 31b, 31c, 31d, 31e, 31f₁, 31f₂, 31g₁, 31g₂, 31h₁, 31h₂, 31i₁, 31i₂, 34, 34a, 34b, 34c, 34d, 34e, 34f₂, 34f₁, 34g₁, 34g₂, 34h₁, 34h₂, 34i₁, 34i₂, 35, 35a, 35b, 35c, 35d, 35e, 35f₁, 35f₂, 35g₁, 35g₂, 35h₁, 35h₂, 35i₁, 35i₂ guide groove, 32, 32a, 32b, 32c, 32d, 32e, 32f₁, 32g₁, 32h₁, 32i₁ first guide groove, 32f₂, 32g₂, 32h₂, 32i₂ third guide groove, 32p first side surface, 32q third side surface, 32r first connection side surface, 32s second connection side surface, 33, 33a, 33b, 33c, 33d, 33e, 33f₁, 33g₁, 33h₁, 33i₁ second guide groove, 33f₂, 33g₂, 33h₂, 33i₂ fourth guide groove, 33p second side surface, 33q fourth side surface, 40 tapered groove, 42p fifth side surface, 42q seventh side surface, 42r third connection side surface, 43p sixth side surface, 43q eighth side surface, F end point, S start point, S1 groove step distance.

1. A method of manufacturing a semiconductor device, the method comprising:
forming a plurality of semiconductor devices arranged in a first region on a main surface of a wafer along a first direction and a second direction that intersects the first direction;
forming a plurality of cleavage groove groups between the plurality of semiconductor devices in the first region on the main surface of the wafer;
forming a cleavage start point in a second region on the main surface of the wafer, the second region being different from the first region; and
cleaving the wafer along a division reference line to separate the plurality of semiconductor devices from each other,
the plurality of cleavage groove groups and the cleavage start point being arranged on the division reference line,
at least one of the plurality of cleavage groove groups being arranged for four semiconductor devices of the plurality of semiconductor devices, the four semiconductor devices being adjacent to each other in the first direction and the second direction,
the plurality of cleavage groove groups each including a plurality of cleavage grooves arranged on the division reference line, and
the plurality of cleavage grooves each having a V-shaped in a cross section that is orthogonal to the division reference line.

2. (canceled)

3. The method of manufacturing a semiconductor device according to claim 1, wherein the forming the cleavage start point includes forming a cleavage start point groove by etching the wafer.

4. The method of manufacturing a semiconductor device according to claim 3, wherein the plurality of cleavage groove groups and the cleavage start point groove are formed in a common step.

5. The method of manufacturing a semiconductor device according to claim 1, wherein the plurality of cleavage grooves each have a first end that is located on an opposite side of the cleavage start point, and the first end has a shape tapered toward the opposite side of the cleavage start point.

6. The method of manufacturing a semiconductor device according to claim 5, wherein the plurality of cleavage grooves each have a second end that is located on a side of the cleavage start point, and the second end has a shape tapered toward the side of the cleavage start point.

7. The method of manufacturing a semiconductor device according to claim 1, wherein the forming the plurality of cleavage groove groups includes forming the plurality of cleavage grooves having bottom surface areas that are equal to each other when seen in a plan view of the main surface of the wafer.

8. The method of manufacturing a semiconductor device according to claim 1, wherein
the plurality of cleavage grooves include a first cleavage groove and a second cleavage groove that are adjacent to each other,
the second cleavage groove is located on an opposite side of the cleavage start point with respect to the first cleavage groove, and
a second groove width of the second cleavage groove is narrower than a first groove width of the first cleavage groove.

9. The method of manufacturing a semiconductor device according to claim 1, wherein the plurality of semiconductor devices are semiconductor lasers or light emitting diodes.

10. The method of manufacturing a semiconductor device according to claim 9, wherein
the plurality of semiconductor devices each include an active region,
the plurality of cleavage groove groups include a first cleavage groove group and a second cleavage groove group,
the first cleavage groove group being adjacent to the active region and located on a side of the cleavage start point with respect to the active region, and
the second cleavage groove group being adjacent to the active region and located on an opposite side of the cleavage start point with respect to active region, and
the forming the plurality of cleavage groove groups includes forming the plurality of cleavage groove groups such that a first distance between the first cleavage groove group and the active region is greater than a second distance between the second cleavage groove group and the active region.

11. The method of manufacturing a semiconductor device according to claim 1, wherein the plurality of semiconductor devices are transistors.
